(19) United States
(12) Patent Application Publication
(10) Pub. No.: US 2026/0114288 A1
(43) Pub. Date: Apr. 23, 2026

(54) SEMICONDUCTOR PACKAGE AND METHOD FOR FORMING THE SAME

(71) Applicant: MEDIATEK INC., Hsinchu City (TW)

(72) Inventors: Sang-Mao CHIU, Hsinchu City (TW); Ya-Jui HSIEH, Hsinchu City (TW); Chi-Yuan CHEN, Hsinchu City (TW); Shih-Chin LIN, Hsinchu City (TW)

(21) Appl. No.: 19/357,273

(22) Filed: Oct. 14, 2025

Related U.S. Application Data
(60) Provisional application No. 63/708,325, filed on Oct. 17, 2024.

(51) Int. Cl. H01L 23/552; H01L 21/48; H01L 23/538; H01L 23/66; H01L 25/065

(52) U.S. Cl. CPC H10W 42/20; H10W 44/20; H10W 70/093; H10W 70/611; H10W 70/65; H10W 90/00; H10W 44/248

(57) ABSTRACT

A semiconductor package and a method for forming a semiconductor package are provided. The semiconductor package includes a first substrate, a first integrated circuit (IC), an antenna, a molding compound, a shielding layer, and a first shielding wall structure. The first substrate includes a first surface and a second surface opposite to each other, The antenna is located close to the first surface of the first substrate. The first integrated circuit (IC) is mounted on the second surface of the first substrate and coupled to the antenna. The molding compound encapsulates the first IC. The shielding layer covers the molding compound. The first shielding wall structure is embedded in the first substrate and coupled to the shielding layer.

### CROSS REFERENCE TO RELATED APPLICATIONS

This application claims the benefit of U.S. provisional application No. 63/708,325, filed on Oct. 17, 2024, the entirety of which is incorporated by reference herein.

### TECHNICAL FIELD

The present disclosure relates to a semiconductor package and a method for forming a semiconductor package, and, in particular, it relates to an antenna package and a method for forming an antenna package.

### BACKGROUND

Wireless communication devices are increasingly popular and increasingly complex. These wireless communication devices typically include antennas to support communication over a range of frequencies. Antenna-in-package (AiP) technology is often used to integrate one or more antennas with other electronic circuits in the same package. AiP technology that implements an antenna integrated into a semiconductor package structure can balance the antenna's performance with overall cost, as well as with a desired reduction in the device size. For example, integrating an antenna and a radio frequency integrated circuit (RFIC) into the same unit can boost the signal and reduce transfer losses.

Although existing antenna package structures generally meet requirements, they have not been satisfactory in all respects. Integrating the antenna and the RFIC in the same unit also brings some challenges. For example, the antenna needs to radiate and receive electromagnetic waves; however, the RFIC should be isolated to prevent electromagnetic waves. This results in a contradiction. Therefore, further improvements in antenna packages are required.

### BRIEF SUMMARY

An embodiment of the present disclosure provides a semiconductor package. The semiconductor package includes a first substrate, a first integrated circuit (IC), an antenna, a molding compound, a shielding layer, and a first shielding wall structure. The first substrate includes a first surface and a second surface opposite to each other, The antenna is located close to the first surface of the first substrate. The first integrated circuit (IC) is mounted on the second surface of the first substrate and is coupled to the antenna. The molding compound encapsulates the first IC. The shielding layer covers the molding compound. The first shielding wall structure is embedded in the first substrate and coupled to the shielding layer.

An embodiment of the present disclosure provides a method for forming a semiconductor package. The method includes forming a first substrate. The first substrate includes a first surface and a second surface opposite to each other, The method further includes forming a first shielding wall structure embedded in the first substrate. The method further includes forming an antenna close to the first surface of the substrate. The method further includes mounting a first integrated circuit (IC) on the second surface of the first substrate and coupled to the antenna. The method further includes forming a molding compound encapsulating the first IC. The method further includes forming a shielding layer covering the molding compound, wherein the first shielding wall structure is coupled to the shielding layer.

### BRIEF DESCRIPTION OF THE DRAWINGS

The present disclosure can be more fully understood by reading the subsequent detailed description and examples with references made to the accompanying drawings, wherein:

FIG. 1 is a schematic cross-sectional view of a semiconductor package in accordance with some embodiments of the disclosure;

FIG. 2A is a schematic top view of a substrate of the semiconductor package in accordance with some embodiments of the disclosure shown in FIG. 1;

FIG. 2B is a cross-sectional view along the line A-A′ (or the line B-B′) of the substrate of the semiconductor package in accordance with some embodiments of the disclosure shown in FIG. 2A;

FIG. 3A is a schematic top view of a substrate of the semiconductor package in accordance with some embodiments of the disclosure shown in FIG. 1;

FIG. 3B is a cross-sectional view along the line A-A′ of the substrate of the semiconductor package in accordance with some embodiments of the disclosure shown in FIG. 3A;

FIG. 4A is a schematic top view of a substrate of the semiconductor package in accordance with some embodiments of the disclosure shown in FIG. 1;

FIG. 4B is a cross-sectional view along the line A-A′ of the substrate of the semiconductor package in accordance with some embodiments of the disclosure shown in FIG. 4A;

FIG. 5A is a schematic top view of a substrate of the semiconductor package in accordance with some embodiments of the disclosure shown in FIG. 1;

FIG. 5B is a cross-sectional view along the line A-A′ of the substrate of the semiconductor package in accordance with some embodiments of the disclosure shown in FIG. 5A;

FIG. 6 is a schematic cross-sectional view of a semiconductor package in accordance with some embodiments of the disclosure;

FIG. 7A is a schematic top view of a substrate of the semiconductor package in accordance with some embodiments of the disclosure shown in FIG. 6;

FIG. 7B is a cross-sectional view along the line A-A′ of the substrate of the semiconductor package in accordance with some embodiments of the disclosure shown in FIG. 7A; and

FIGS. 8A, 8B, 8C, 8D, 8E, 9A, 9B, 9C, 9D and 9E are schematic cross-sectional views at different stages of forming the shielding wall structure of the semiconductor package in accordance with some embodiments of the disclosure shown in FIGS. 2B, 3B, 4B, 5B, and 7B.

### DETAILED DESCRIPTION

The following description is made for the purpose of illustrating the general principles of the disclosure and should not be taken in a limiting sense. The scope of the disclosure is best determined by reference to the appended claims.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

For electromagnetic compatibility (EMC) and electromagnetic interference (EMI) consideration, conformal shielding by sputtering is often coated on the entire outline of a semiconductor package. For antenna-in-module/package (AiM/AiP) application, the aforementioned conformal shielding may block antennas for receiving signals from and/or transmitting signals to external devices. Therefore, a partial shielding needs to be selectively and effectively implemented.

The conventional AiM/AiP is usually fabricated by laterally extending the ground traces to be exposed from the sidewalls of the substrate, so that the partial shielding can be partially coated on the sidewall portion of the substrate surrounding the ground traces without blocking the sidewall portion of the substrate surrounding the antenna. However, the conventional partial shielding brings lots of difficulty in processes. For example, the precision of vertical height of the partial shielding is difficult to be controlled. The tooling fee and the tooling maintenance fee for the partial shielding are costly. The conventional partial shielding is coated on the fabricated AiM/AiP unit cell, so that the conventional AiM/AiP is suffered from low throughput. Thus, a novel AiM/AiP package is needed.

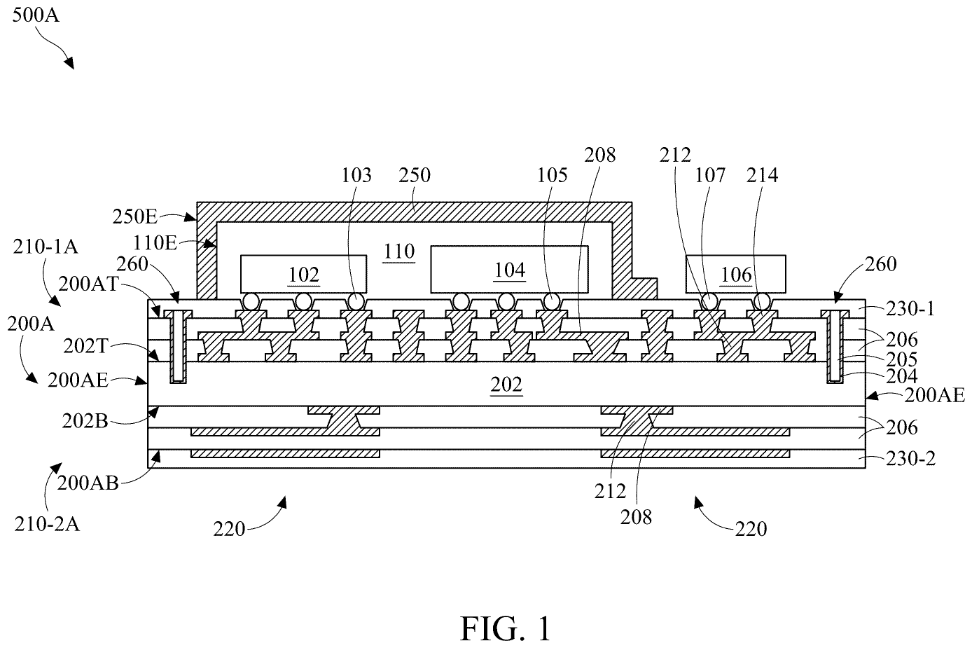

FIG. 1 is a schematic cross-sectional view of a semiconductor package 500A in accordance with some embodiments of the disclosure. In some embodiments, the semiconductor package 500A may include an antenna package. The semiconductor package 500A includes a substrate 200A, integrated circuit (ICs) 102 and 104, an antenna 220, a molding compound 110, a shielding layer 250 and a shielding wall structure 260 (including shielding wall structures 260A, 260B, 260C, and 260D in the following figures).

As shown in FIG. 1, the substrate 200A may include a multi-layered package substrate. The substrate 200A may provide mechanical support and electrical connections between integrated circuit (IC) chips and conductive bumps attached to the top surface 200AT and the bottom surface 200AB of the substrate 200A. The substrate 200A may have various types including, for example, cored substrates, including thin core, thick core (e.g., laminate BT (bismaleimide-triazine resin) or FR-4 type fibrous board material), and laminate core. Alternatively, the cored package substrates, for example, can be built up layer by layer around a central core, with layers of conductive material (usually copper) separated by layers of insulating dielectric, with interlayer connections being formed with through holes or vias (microvias).

The substrate 200A may have various types including, for example, a core substrate or a coreless substrate (e.g., the laminate substrate). In some embodiments in which the substrate 200A is a core substrate, the substrate 200A includes a core 202 and redistribution layers (RDLs) 210-1A and 210-2A. The core 202 has a top surface 202T and a bottom surface 202B. In some embodiments, the core 202 may be formed of an organic material, a glass material, a ceramic material, a semiconductor material, the like, or a combination thereof. The organic material may include polypropylene, prepreg (PP), fiberglass resin (e.g., FR-4), bismaleimide triazine (BT) resin, the like, or a combination thereof. The semiconductor material may include silicon, germanium, or a compound material, including silicon germanium, silicon carbide, gallium arsenic, silicon germanium carbide, the like, or a combination thereof. The redistribution layer structures 210-1A and 210-2A are disposed on the top surface 202T and the bottom surface 202B of the core 202, respectively. In some embodiments, each of the redistribution layer structures 210-1A and 210-2A includes conductive traces 208, vias 212 disposed in one or more dielectric layers 206. In addition, the redistribution layer structures 210-1A may further include conductive pads 214.

In some embodiments, the dielectric layers 206 of the redistribution layer structures 210-1A and 210-2A are symmetrically disposed the top surface 202T and the bottom surface 202B of the core 202. For example, the number of dielectric layers 206 of the redistribution layer structure 210-1A is the same as the number of dielectric layers 206 of the redistribution layer structures 210-2A. In some embodiments, the dielectric layers 206 may be formed of organic polymer, including polyimide (PI), polybenzoxazole (PBO), benzocyclobutene (BCB), epoxy, Ajinomoto build-up film (ABF), Bismaleimide-Triazine (BT resin), another suitable organic dielectric material, or a combination thereof, but it is not limited thereto. Alternatively, the dielectric layers 206 may be formed of silicon oxide, silicon nitride, silicon oxynitride, the like, or a combination thereof. In some embodiments, the dielectric layers 206 may be formed by a lamination process, a spin coating process, a chemical vapor deposition (CVD) process, or another applicable process. In accordance with some embodiment, the dielectric layers 206 may be patterned through one or more photolithography processes and/or etching processes.

In some embodiments, the redistribution layer structure 210-1A is located between the core 202 and the integrated circuit (ICs) 102 and 104. The redistribution layer structure 210-1A includes electrical routings composed of the conductive traces 208 and the vias 212 formed in the dielectric layers 206 and the conductive pads 214 for electrical connections between the integrated circuit (ICs) 102 and 104 on the redistribution layer structure 210-1A and the antenna 220 in the redistribution layer structure 210-2A.

The conductive traces 208 are formed within the dielectric layers 206 at different levels. In some embodiments, the conductive layer 208 at each of levels of the redistribution layer structure 210-1A may include power traces, signal traces or ground traces, which are used for the input/output (I/O) connections of the ICs 102 and 104.

As shown in FIG. 1, the vias 212 disposed in the dielectric layers 206 of the redistribution layer structure 210-1A. The vias 212 may be formed passing through the dielectric layers 206 of the redistribution layer structures 210-1A and 210-2A to be coupled to different levels of the conductive traces 208.

The conductive pads 214 of the redistribution layer structure 210-1A are disposed close to the top surface 200ATof the substrate 200A. The conductive pads 214 are coupled to different terminals of the conductive traces 208. The conductive pads 214 close to the top surface 200AT of the substrate 200A are used for the ICs 102 and 104 mounted directly on them.

In some embodiments, the redistribution layer structure 210-2A is located on the bottom surface 202B of the core 202 and opposite the redistribution layer structure 210-1A. In addition, the redistribution layer structure 210-2A is separated from the ICs 102 and 104 via the core 202 and the redistribution layer structure 210-1A. The redistribution layer structure 210-2A includes the conductive traces 208, the vias 212 and the antenna 220 formed in the dielectric layers 206. The antenna 220 is formed in the dielectric layers 206 of the first substrate 200A far from the ICs 102 and 104. The antenna 220 is composed of the conductive layers and vias. In addition, the redistribution layer structure 210-2A may further include radiators, feeding lines, another suitable components, or a combination thereof.

In some embodiments, the conductive traces 208, the vias 212 and the conductive pads 214 include a conductive material, such as metals including tungsten, titanium, tantalum, ruthenium, cobalt, copper, aluminum, platinum, tin, silver, gold, the like, an alloy thereof, or a combination thereof.

It should be noted that the number of vias 212, the number of conductive traces 208, and the number of dielectric layers 206 of the redistribution layer structures 210-1A and 210-2A, the number of conductive pads 214 of the redistribution layer structure 210-1A, and the number of antennas 220 of the redistribution layer structure 210-2A shown in FIG. 1 are only an example and is not a limitation to the present disclosure.

In some embodiments, the substrate 200A further includes further includes plated through hole (PTHs) (not shown) formed passing through the core 202 and embedded it. The PTHs are coupled between the redistribution layer structures 210-1A and 210-2A. For example, the antenna 220 of the redistribution layer structure 210-2A may be coupled to the electrical routings of the redistribution layer structure 210-1A via the PTHs.

In some embodiments in which the substrate 200A is a coreless substrate, the substrate 200A is fabricated without the core, and the redistribution layer structures 210-2A is laminated on the redistribution layer structure 210-1A (or vice versa).

As shown in FIG. 1, the semiconductor package 500A further includes passivation layers 230-1, 230-2 disposed over the corresponding redistribution layer structures 210-1A and 210-2A. The passivation layer 230-1 may have openings (not shown) to expose corresponding conductive pads 214 coupled to the conductive traces 208. In addition, the passivation layers 230-2 may completely cover the antenna 220. The passivation layers 230-1, 230-2 may include a solder resist layer. In some embodiments, the passivation layers 230-1, 230-2 may be formed of a resin material (such as a thermosetting resin, a photosensitive resin, or the like), an ink material, a tape material (such as polyimide tape, Kapton tape, or the like), the like, or a combination thereof. The passivation layers 230-1, 230-2 may be formed by printing, coating, or another suitable methods.

The ICs 102 and 104 are disposed on the substrate 200A and coupled to the conductive pads 214 of the redistribution layer structure 210-1A of the substrate 200A by conductive structures 103 and 105. In addition, the ICs 102 and 104 may be coupled to the antenna 220 by the conductive structures 103 and 105 and the redistribution layer structure 210-1A. In some embodiment, the ICs 102 and 104 include a radio frequency integrated circuit (RFIC), a power management integrated circuit (PMIC) or a combination thereof. In some embodiment, the ICs 102 and 104 include electronic components other than passive components. In some embodiments, the conductive structures 103 and 105 include a conductive ball structure such as a copper ball, a conductive bump structure such as a copper bump or a solder bump structure, or a conductive pillar structure such as a copper pillar structure. For example, the conductive structures 103 and 105 may be microbumps, controlled collapse chip connection (C4) bumps, solder balls, ball grid array (BGA) balls, another suitable conductive connector, or a combination thereof.

As shown in FIG. 1, the semiconductor package 500A may further include connector component 106 formed over the top surface 200AT of the substrate 200A. The connector component 106 may be adjacent to the ICs 102 and 104. The connector component 106 may be coupled to the ICs 102 and 104 via conductive structures 107 and the electrical routings of the redistribution layer structure 210-1A. In some embodiments, the connector component 106 includes a divider/combiner. In some embodiments, the conductive structures 103, 105 and 107 may include the same or similar structure.

The ICs 102 and 104 and the connector component 106 may be disposed over the same surface (e.g., the top surface 200AT) of the substrate 200A, and may be arranged close to the electrical routings of the redistribution layer structure 210-1A and far from the antenna 220. The ICs 102 and 104 and the connector component 106 may be arranged on the side of the substrate 200A which is opposite to the antenna 220.

As shown in FIG. 1, the molding compound 110 may partially cover the substrate 200A and encapsulate the ICs 102 and 104. In addition, the connector component 106 may be exposed from the molding compound 110, so that the semiconductor package 500A may be electrically coupled to other electronic components, such as a printed circuit board (PCB) or any suitable component (not illustrated), through the connector component 106. In some embodiments, the molding compound 110 is made of a material including, for example, a Novolac-based resin, an epoxy-based resin, a silicone-based resin, or another suitable encapsulant. The molding compound 110 may include suitable fillers, such as powdered SiO₂. The molding compound 110 can be applied using any of a number of molding techniques, such as compression molding, injection molding, or transfer molding.

The shielding layer 250 is disposed on the passivation layers 230-1 to cover the molding compound 110 the ICs 102 and 104. The shielding layer 250 may extend to partially cover the redistribution layer structure 210-1A. In addition, the shielding layer 250 does not cover a sidewall 200AE of the substrate 200A. In some embodiments, the shielding layer 250 may include a conductive material, such as metals including copper, aluminum, the like, an alloy thereof, or a combination thereof. In some embodiments, the shielding layer 250 may be formed by a deposition process, such as sputtering.

As shown in FIG. 1, a sidewall 200AE of the substrate 200A away from the connector component 106 is protrude from a corresponding sidewall 250AE of the shielding layer 250 and a corresponding sidewall 110E of the molding compound 110. Therefore, the shielding layer 250 does not cover the sidewall 200AE of the substrate 200A. The shielding layer 250 is not required to be precisely controlled during the fabrication process. In addition, the shielding layer 250 may have a simple fabrication process and a reduced fabrication cost. Accordingly, the shielding layer 250 is feasible and beneficial for mass production that boosts output and reduces costs.

As shown in FIG. 1, the shielding wall structure 260 is embedded in the substrate 200A. The shielding wall structure 260 is exposed from the surface 200AT of the substrate 200A and completely covered by the passivation layer 230-1. In some embodiments, the shielding wall structure 260 is embedded in at least one dielectric layer 206 of the RDL structure 210-1A. In some embodiments, the shielding wall structure 260 may pass through at least one dielectric layer 206 of the RDL structure 210-1A. In some embodiments where the substrate 200A is a core substrate, the shielding wall structure 260 may be embedded in at least one dielectric layer 206 and the core. In some embodiments, the shielding wall structure 260 is coupled to the shielding layer 250 through the following achievements: (1) the shielding wall structure 260 is coupled to the shielding layer 250 (or an extension portion of the shielding layer 250) through the via; (2) the shielding wall structure 260 is coupled to the conductive trace 208 that is located at a certain level of the redistribution layer structure 210-1A and exposed form the sidewall 200AE of the substrate 200A, and the shielding layer 250 has an extension portion to connect to the exposed conductive trace 208, in which the achievement (1) is more easy and practical for production. Furthermore, the shielding wall structure 260 and the shielding layer 250 may be coupled by at least one ground trace (belong to a portion of the conductive traces 208) of the substrate 200A. The shielding wall structure 260 and the shielding layer 250 may prevent signals transmitted by the antenna 220 in a direction toward the ICs 102 and 104 and the electrical routings of the redistribution layer structure 210-1A, thereby reducing electromagnetic wave interference.

In some embodiments, the shielding wall structure 260 may include a non-conductive material wall 205 and a conductive material 204. The non-conductive material wall 205 is formed from the top of the redistribution layer structure 210-1A and extends into a portion of the substrate 200A. In some embodiments, the conductive material 204 may be formed as a thin conductive layer covering sidewalls and the bottom surface of the non-conductive material wall 205. In some embodiments, the non-conductive material wall 205 includes epoxy resin, such as an ink. In some embodiments, the conductive material 204 include copper or nickel-copper and are formed by a plating process, such as chemical plating, electroplating or electro-less plating.

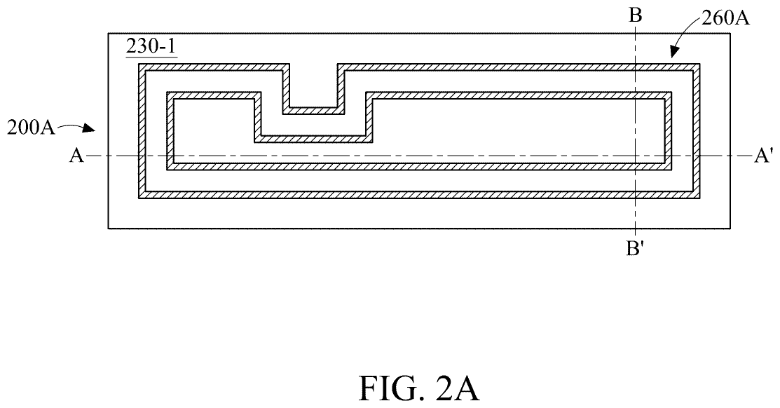

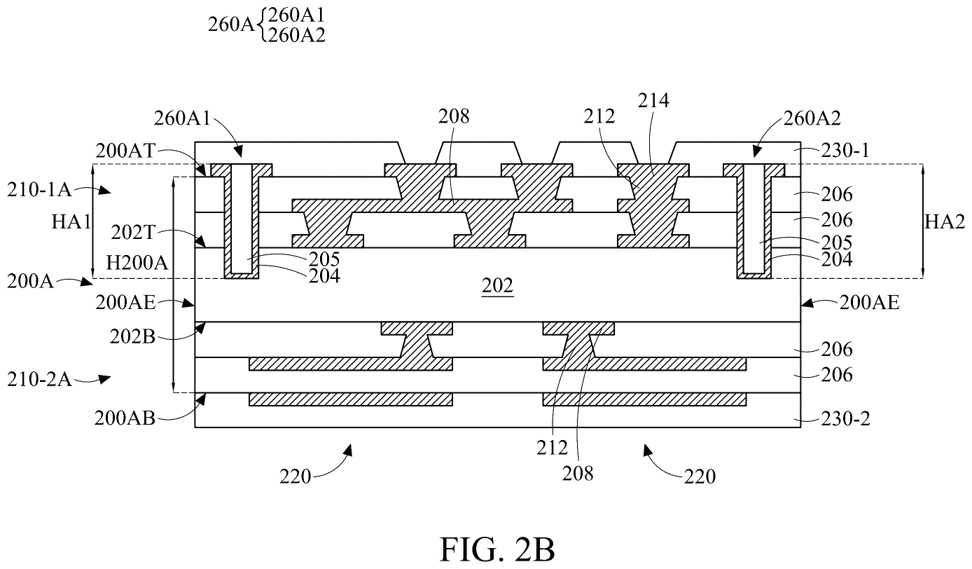

The structures and arrangements of the shielding wall structures 260A, 260B, 260C, and 260D will be illustrated in FIGS. 2A, 2B, 3A, 3B, 4A, 4B, 5A, and 5B.

FIG. 2A is a schematic top view of the substrate 200A of the semiconductor package 500A in accordance with some embodiments of the disclosure shown in FIG. 1. FIG. 2B is a cross-sectional view along the line A-A′ (or the line B-B′) of the substrate 200A of the semiconductor package 500A in accordance with some embodiments of the disclosure shown in FIG. 2A. FIGS. 2A and 2B also illustrate the structure and arrangement of the shielding wall structure 260A. Elements of the embodiments that are the same or similar to those previously described with reference to FIG. 1 are not repeated herein, in the interests of brevity. For illustration, the elements below the passivation layer 230-1 except for the shielding wall structure 260A are omitted in FIG. 2A.

As shown in FIGS. 2A and 2B, the shielding wall structure 260A may form a single closed pattern to surround the electrical routings (including at least one conductive trace 208, at least one via 212 and at least one conductive pad 214) of the redistribution layer structure 210-1A of the substrate 200A coupled to the ICs 102 and 104 (FIG. 1). In some embodiments, as shown in FIG. 2A, the shielding wall structure 260A is a continuous pattern without any disconnected parts. The shielding wall structure 260A may also be a closed and continuous pattern. The shielding wall structure 260A is separated from the sidewall 200AE of the substrate 200A. In other words, the shielding wall structure 260A is not exposed from the sidewall 200AE of the substrate 200A. In this embodiment, the shielding wall structure 260A may include portions 260A1 and 260A2, as shown in FIG. 2B. The portion 260A1 has height HA1. The portion 260A2 has height HA2. In this embodiment, the height HA1 and the height HA2 may have substantially the same value. In this embodiment, the height HA1 and the height HA2 may be smaller than or equal to half a thickness H200A of the substrate 200A. For example, the portions 260A1 and 260A2 of the shielding wall structure 260A may pass through the RDL structure 210-1A and extend into a portion of the core 202. In some embodiments, the height HA1 and the height HA2 may have different value. In some embodiments, at least one portion (such as the portions 260A1 and 260A2) of the shielding wall structure 260A does not pass through the substrate 200A to ensure the mechanical strength and structural stability of the substrate. In other words, at least one portion (such as the portions 260A1 and 260A2) of the shielding wall structure 260A has a height (such as the height HA1 and the height HA2) smaller than the thickness H200A of the substrate 200A to ensure the mechanical strength and structural stability of the substrate.

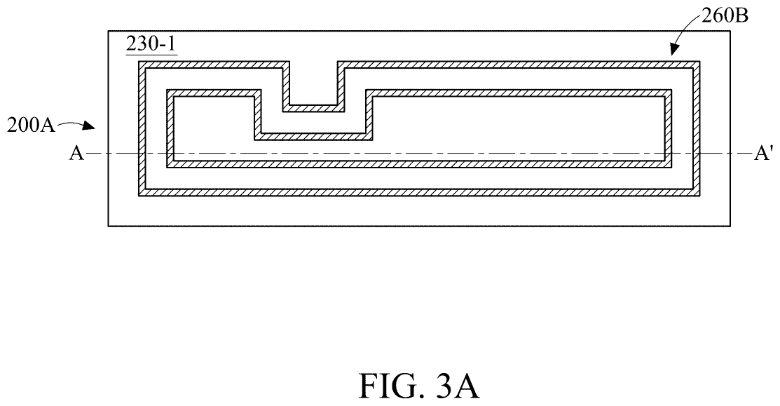

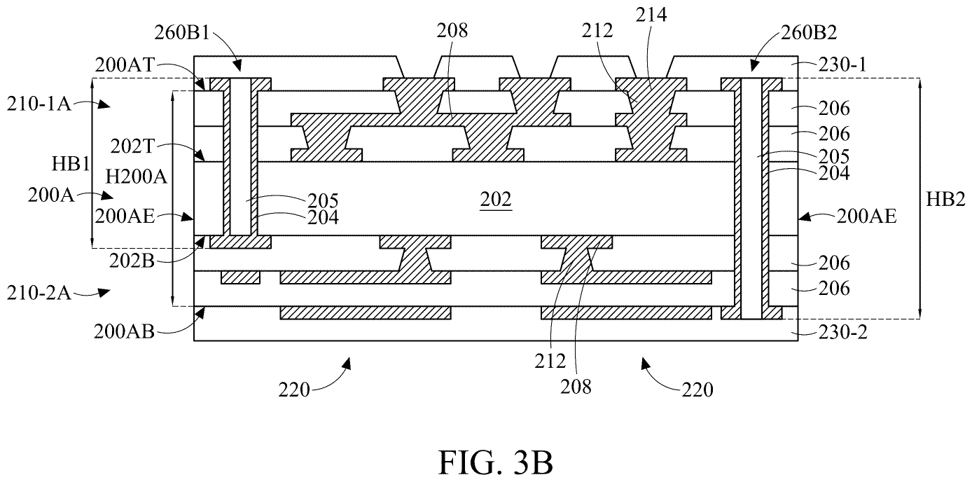

FIG. 3A is a schematic top view of the substrate 200A of the semiconductor package 500A in accordance with some embodiments of the disclosure shown in FIG. 1. FIG. 3B is a cross-sectional view along the line A-A′ of the substrate 200A of the semiconductor package 500A in accordance with some embodiments of the disclosure shown in FIG. 3A. FIGS. 3A and 3B also illustrate the structure and arrangement of the shielding wall structure 260B. Elements of the embodiments that are the same or similar to those previously described with reference to FIGS. 1, 2A, and 2B are not repeated herein, in the interests of brevity. For illustration, the elements below the passivation layer 230-1 except for the shielding wall structure 260B are omitted in FIG. 3A.

As shown in FIGS. 3A and 3B, the shielding wall structure 260B may form a single closed pattern to surround the electrical routings (including at least one conductive trace 208, at least one via 212 and at least one conductive pad 214) of the substrate 200A coupled to the ICs 102 and 104 (FIG. 1). The shielding wall structure 260B is separated from the sidewall 200AE of the substrate 200A. In other words, the shielding wall structure 260B is not exposed from the sidewall 200AE of the substrate 200A. In this embodiment, the shielding wall structure 260B may include portions 260B1 and 260B2 having different heights HB1 and HB2, as shown in FIG. 3B. For example, the portion 260B1 of the shielding wall structure 260B may pass through the RDL structure 210-1A and the core 202. The portion 260B2 of the shielding wall structure 260B may pass through the RDL structure 210-1A, the core 202, and the RDL structure 210-2A. In this embodiment, the portion 260B1 of the shielding wall structure 260B may be exposed form the top surface 200AT of the substrate 200A and the bottom surface 202B of the core 202. The portion 260B2 of the shielding wall structure 260B may be exposed form the top surface 200AT and the bottom surface 200AB of the substrate 200A of the core 202. In this embodiment, the height HB2 of the portion 260B2 is greater than the height HB1 of the portion 260B1. In this embodiment, the height HB1 and HB2 may be greater than half the thickness H200A of the first substrate 200A. The height HB1 may be smaller than the thickness H200A of the substrate 200A. In some embodiments, the height HB2 may be greater than half the thickness H200A of the substrate 200A, while the height HB1 may be less than or equal to half the thickness H200A of the substrate 200A. In some embodiments, at least one portion (such as the portion 260B1) of the shielding wall structure 260B does not pass through the substrate 200A to ensure the mechanical strength and structural stability of the substrate. In other words, at least one portion (such as the portion 260B1) of the shielding wall structure 260B has a height (such as the height HB1) smaller than the thickness H200A of the substrate 200A to ensure the mechanical strength and structural stability of the substrate.

In this embodiment, since the portion 260B2 of the shielding wall structure 260B passes through the substrate 200A, the portion 260B1 of the shielding wall structure 260B may be designed not to passes through the RDL structure 210-2A of the substrate 200A having the antenna 220 embedded in it, so that the portion of substrate 200A surrounded by the shielding wall structure 260B may keep connect to other portions of the substrate 200A. The integrity of the substrate 200A can be maintained accordingly.

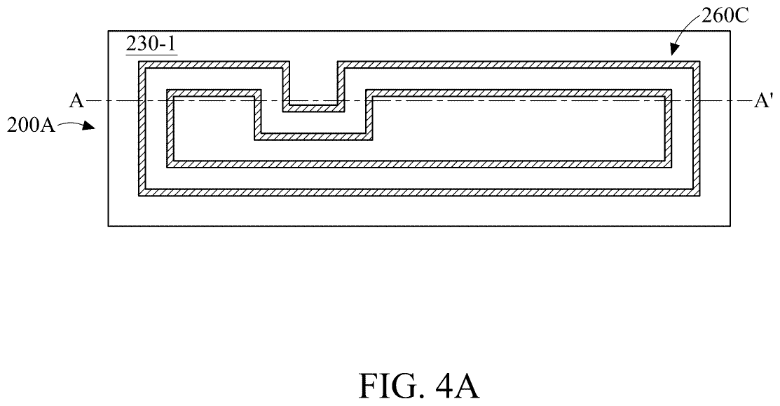

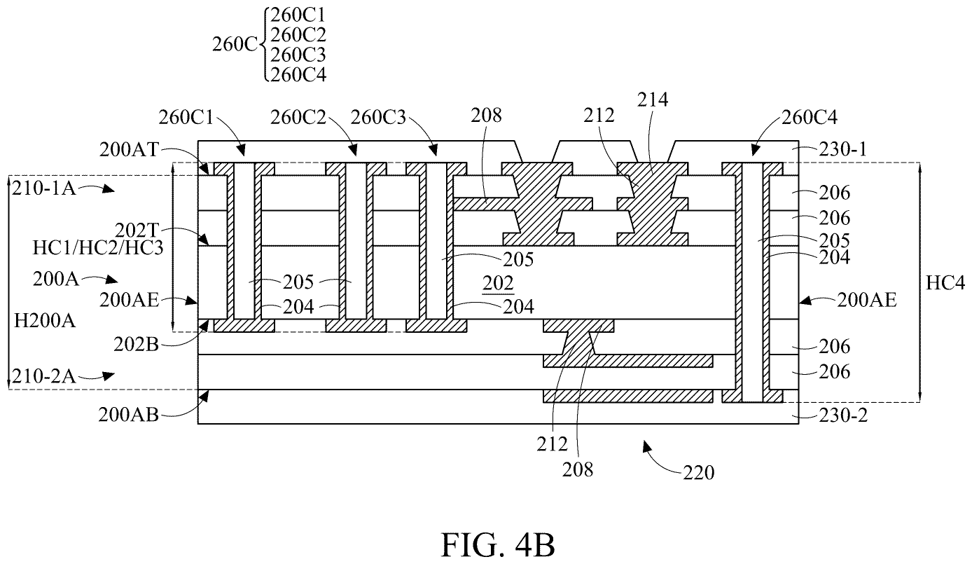

FIG. 4A is a schematic top view of the substrate 200A of the semiconductor package 500A in accordance with some embodiments of the disclosure shown in FIG. 1. FIG. 4B is a cross-sectional view along the line A-A′ of the substrate 200A of the semiconductor package 500A in accordance with some embodiments of the disclosure shown in FIG. 4A. FIGS. 4A and 4B also illustrate the structure and arrangement of the shielding wall structures260C. Elements of the embodiments that are the same or similar to those previously described with reference to FIGS. 1, 2A, 2B, 3A, and 3B are not repeated herein, in the interests of brevity. For illustration, the elements below the passivation layer 230-1 except for the shielding wall structure 260C are omitted in FIG. 4A.

As shown in FIGS. 4A and 4B, the shielding wall structure 260C may form a single closed pattern to surround the electrical routings (including at least one conductive trace 208, at least one via 212 and at least one conductive pad 214) of the substrate 200A coupled to the ICs 102 and 104 (FIG. 1). In some embodiments, as shown in FIG. 4A, the shielding wall structure 260C forms a closed and continuous pattern without any disconnected parts. The shielding wall structure 260C is separated from the sidewall 200AE of the substrate 200A. In other words, the shielding wall structure 260C is not exposed from the sidewall 200AE of the substrate 200A. In this embodiment, the shielding wall structure 260C may include portions 260C1, 260C2, 260C3 and 260C4, as shown in FIG. 4B. The portion 260C1 has height HC1. The portion 260C2 has height HC2. The portion 260C3 has height HC3. The portion 260C4 has height HC4. For example, the portions 260C1, 260C2, and 260C3 of the shielding wall structure 260C may pass through the RDL structure 210-1A and the core 202. The portion 260C4 of the shielding wall structure 260C may pass through the RDL structure 210-1A, the core 202, and the RDL structure 210-2A. In this embodiment, the portions 260C1, 260C2, and 260C3 of the shielding wall structure 260C may be exposed form the top surface 200AT of the substrate 200A and the bottom surface 202B of the core 202. The portion 260C4 of the shielding wall structure 260C may be exposed form the top surface 200AT and the bottom surface 200AB of the substrate 200A of the core 202. In this embodiment, the height HC1 of portion 260C1, the height HC2 of portion 260C2, and the height HC3 of portion 260C3 may have substantially the same value. In addition, the height HC4 of portion 260C4 is greater than the height HC1 of portion 260C1, the height HC2 of portion 260C2, and the height HC3 of portion 260C3. In this embodiment, the height HC4 may be greater than half the thickness H200A of the first substrate 200A. The heights HC1, HC2, HC3 may be smaller than the thickness H200A of the substrate 200A. In some embodiments, at least one portion (such as the portions 260C1, 260C2, and 260C3) of the shielding wall structure 260C does not pass through the substrate 200A to ensure the mechanical strength and structural stability of the substrate. In other words, at least one portion (such as the portions 260C1, 260C2, and 260C3) of the shielding wall structure 260B has a height (such as the heights HC1, HC2, HC3) smaller than the thickness H200A of the substrate 200A to ensure the mechanical strength and structural stability of the substrate.

In this embodiment, since the portion 260C4 of the shielding wall structure 260B passes through the substrate 200A, the portions 260C1, 260C2, and 260C3 of the shielding wall structure 260B may be designed not to passes through the RDL structure 210-2A of the substrate 200A having the antenna 220 embedded in it, so that the portion of substrate 200A surrounded by the shielding wall structure 260C may keep connect to other portions of the substrate 200A. The integrity of the substrate 200A can be maintained accordingly.

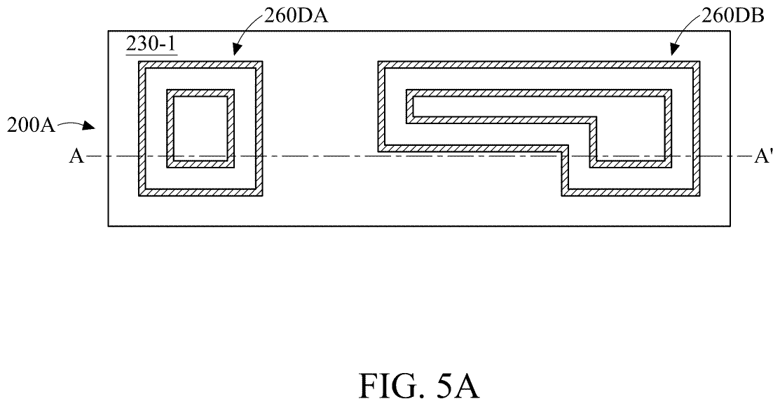

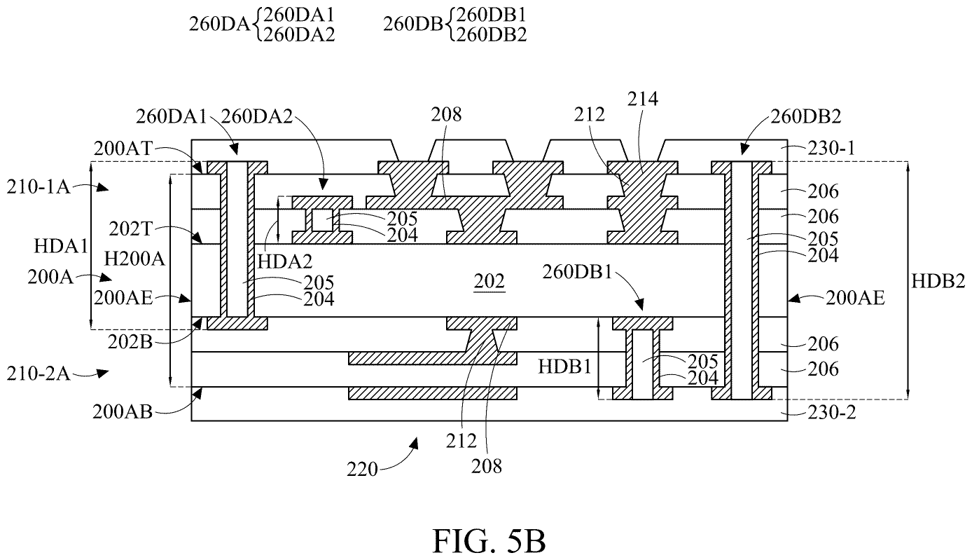

FIG. 5A is a schematic top view of the substrate 200A of the semiconductor package 500A in accordance with some embodiments of the disclosure shown in FIG. 1. FIG. 5B is a cross-sectional view along the line A-A′ of the substrate 200A of the semiconductor package 500A in accordance with some embodiments of the disclosure shown in FIG. 5A. FIGS. 5A and 5B also illustrate the structure and arrangement of the shielding wall structure 260D (including shielding wall structures 260DA and 260DB). Elements of the embodiments that are the same or similar to those previously described with reference to FIGS. 1, 2A, 2B, 3A, 3B, 4A, and 4B are not repeated herein, in the interests of brevity. For illustration, the elements below the passivation layer 230-1 except for the shielding wall structures 260DA and 260DB are omitted in FIG. 5A.

As shown in FIGS. 5A and 5B, the semiconductor package 500A may include multiple shielding wall structures 260DA and 260DB embedded in the substrate 200A and coupled to the shielding layer 250. The shielding wall structures 260DA and 260DB may form closed patterns separated from each other to surround the electrical routings (including at least one conductive trace 208, at least one via 212 and at least one conductive pad 214) of the substrate 200A coupled to the ICs 102 and 104 (FIG. 1). In some embodiments, as shown in FIG. 5A, the shielding wall structures 260DA and 260DB each form a closed and continuous pattern without any disconnected parts. The shielding wall structures 260DA and 260DB may be independent patterns with no intersection or interference between them. The shielding wall structures 260DA and 260DB are separated from the sidewall 200AE of the substrate 200A. In other words, the shielding wall structures 260DA and 260DB are not exposed from the sidewall 200AE of the substrate 200A. In this embodiment, at least one of the shielding wall structures 260DA and 260DB is coupled to the shielding layer 250 by at least one conductive trace 208 of the substrate 200A.

As shown in FIG. 5B, in this embodiment, the shielding wall structure 260DA may include portions 260DA1 and 260DA2 having heights HDA1 and HDA2. The shielding wall structure 260DB may include portions 260DB1 and 260DB2 having heights HDB1 and HDB2. For example, the portion 260DA1 of the shielding wall structure 260DA may pass through the RDL structure 210-1A and the core 202. The portion 260DA2 of the shielding wall structure 260DA may pass through one dielectric layer 206 of the RDL structure 210-1A. The portion 260DB1 of the shielding wall structure 260DB may pass through two dielectric layers 206 of the RDL structure 210-2A. The portion 260DB2 of the shielding wall structure 260DB may pass through the RDL structure 210-1A, the core 202, and the RDL structure 210-2A. In this embodiment, the height HDB2 of portion 260DB2 is greater than the height HDA1 of portion 260DA1. The height HDA1 of portion 260DA1 is greater than the height HDB1 of portion 260DB1. The height HDB1 of portion 260DB1 is greater than the height HDA2 of portion 260DA2. In this embodiment, the heights HDA1 and HDB2 may be greater than half the thickness H200A of the first substrate 200A. The heights HDA2 and HDB1 may be smaller than half the thickness H200A of the substrate 200A.

In this embodiment, since the portion 260DB2 of the shielding wall structure 260DB passes through the substrate 200A, the portion 260DB1 of the shielding wall structure 260B may be designed not to passes through the substrate 200A, so that the portion of substrate 200A surrounded by the shielding wall structure 260DB may keep connect to other portions of the substrate 200A. The integrity of the substrate 200A can be maintained accordingly.

In some embodiments, the number, shape (top-view shape), heights of portions of the shielding wall structures 260A, 260B, 260C, and 260DA and 260DB shown in FIGS. 2A, 2B, 3A, 3B, 4A, 4B, and 5A, 5B are only an example and is not a limitation to the present disclosure.

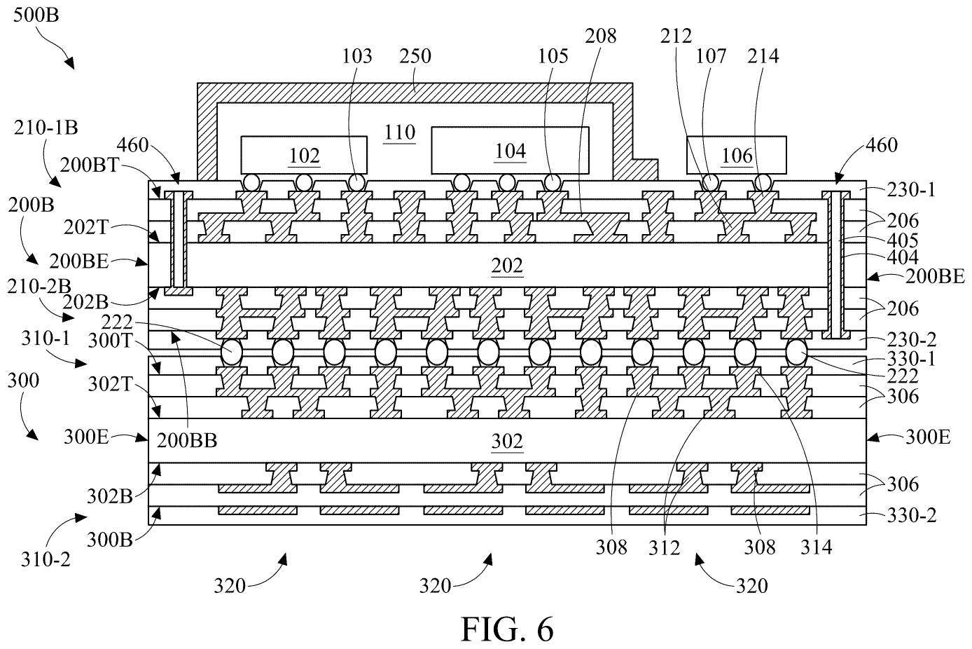

FIG. 6 is a schematic cross-sectional view of a semiconductor package 500B in accordance with some embodiments of the disclosure. Elements of the embodiments that are the same or similar to those previously described with reference to FIG. 1 are not repeated herein, in the interests of brevity.

The semiconductor package 500B includes a substrate 200B, integrated circuit (ICs) 102 and 104, passivation layers 230-1, 230-2, connector component 106, a molding compound 110, a shielding layer 250, a substrate 300, an antenna 320 and a shielding wall structure 460.

As shown in FIG. 6, the substrate 200B may include a multi-layered package substrate. The substrate 200B may provide mechanical support and electrical connections between the integrated circuits (ICs) 102, 104 and conductive structures 222 attached to the top surface 200BT and the bottom surface 200BB of the substrate 200B. In some embodiments, the substrate 200B includes a core 202 and redistribution layers (RDLs) 210-1B and 210-2B. The redistribution layer structures 210-1B and 210-2B are disposed on the top surface 202T and the bottom surface 202B of the core 202, respectively. In some embodiments, each of the redistribution layer structures 210-1B and 210-2B includes conductive traces 208, vias 212 disposed in one or more dielectric layers 206, and conductive pads 214.

In this embodiment, each of the redistribution layer structures 210-1B and 210-2B includes electrical routings composed of conductive traces 208 and vias 212 formed in the dielectric layers 206 for electrical connections between the integrated circuit (ICs) 102 and 104 on the redistribution layer structure 210-1B. In this embodiment, there is no antenna disposed in the redistribution layer structures 210-1B and 210-2B of the substrate 200B. Therefore, the substrate 200B may be also called a routing substrate for the integrated circuit (ICs) 102 and 104.

In this embodiment, the conductive traces 208 are formed within the dielectric layers 206 at different levels. In some embodiments, the conductive layer 208 at each of levels of the redistribution layer structures 210-1B and 210-2B may include power traces, signal traces or ground traces, which are used for the input/output (I/O) connections of the ICs 102 and 104.

As shown in FIG. 1, the vias 212 disposed in the dielectric layers 206 of the redistribution layer 210-1B and 210-2B. The vias 212 may be formed passing through the dielectric layers 206 of the redistribution layer structures 210-1B and 210-2B to be coupled to different levels of the conductive traces 208.

The conductive pads 214 are disposed close to the top surface 200BT and the bottom surface 200AB of the substrate 200B. The conductive pads 214 are coupled to different terminals of the conductive traces. The conductive pads 214 of the redistribution layer structure 210-1B close to the top surface 200BT of the substrate 200B are used for the ICs 102 and 104 mounted directly on them. The conductive pads 214 of the redistribution layer structure 210-2B close to the bottom surface 200BB of the substrate 200B are used for conductive structures 222 mounted on them. Therefore, the substrate 200B can be mounted on and coupled to the substrate 300 via the conductive structures 222. In some embodiments, the conductive structures 222 include a conductive ball structure such as a copper ball, a conductive bump structure such as a copper bump or a solder bump structure, or a conductive pillar structure such as a copper pillar structure. For example, the conductive structures 222 may be microbumps, controlled collapse chip connection (C4) bumps, solder balls, ball grid array (BGA) balls, another suitable conductive connector, or a combination thereof.

As shown in FIG. 6, the semiconductor package 500B further includes passivation layers 230-1, 230-2 disposed over the corresponding redistribution layer structures 210-1B and 210-2B. In addition, the passivation layers 230-1, 230-2 may have openings (not shown) to expose corresponding conductive pads 214 coupled to the conductive traces 208.

The ICs 102 and 104 are disposed on the top surface 200BT the substrate 200B and coupled to the conductive pads 214 of the redistribution layer structure 210-1B of the substrate 200B by conductive structures 103 and 105.

As shown in FIG. 6, the semiconductor package 500B may further include connector component 106 formed over the top surface 200BT of the substrate 200B. The connector component 106 may be adjacent to the ICs 102 and 104. The connector component 106 may be coupled to the ICs 102 and 104 via the redistribution layer structure 210-1B of the substrate 200B.

As shown in FIG. 6, the molding compound 110 may partially cover the substrate 200A and encapsulate the ICs 102 and 104. In addition, the connector component 106 may be exposed from the molding compound 110.

The shielding layer 250 is disposed to cover the molding compound 110 the ICs 102 and 104. the shielding layer 250. In addition, the shielding layer 250 does not cover a sidewall 200BE of the substrate 200B. The shielding layer 250 may extend to partially cover the redistribution layer structure 210-1B.

As shown in FIG. 6, the substrate 300 is mounted on the bottom surface 200BB of the substrate 200B. The substrate 300 has a top surface 300T and a bottom surface 300B. The top surface 300T of the substrate 300 faces the bottom surface 200BB of the substrate 200B and is provided for the substrate 200B mounting on it. In this embodiment, the antenna 320 is disposed in the substrate 300. Therefore, the substrate 300 may be also called an antenna substrate. In this embodiment, the shielding layer 250 does not cover a sidewall 300E of the second substrate 300.

In some embodiments, the substrates 200A and 300 may have the similar structure and arrangement, except that the substrate 300 does not have any shielding wall structure embedded in it.

As shown in FIG. 6, in some embodiments, the substrate 300 includes a core 302 and redistribution layers (RDLs) 310-1 and 310-2. The redistribution layer structures 310-1 and 310-2 are disposed on the top surface 302T and the bottom surface 302B of the core 302, respectively. In some embodiments, each of the redistribution layer structures 310-1 and 310-2 includes conductive traces 308, vias 312 disposed in one or more dielectric layers 306, and conductive pads 314. Alternatively, the substrate 300 is fabricated without the core, and the redistribution layer structures 310-1 is laminated on the redistribution layer structure 310-2 (or vice versa).

In some embodiments, the dielectric layers 206 and 306 may have the same or similar materials and structures. The conductive traces 208 and 308 may have the same or similar materials and structures. The vias 212 and 312 may have the same or similar materials and structures. The conductive pads 214 and 314 may have the same or similar materials and structures.

In some embodiments, the redistribution layer structure 310-1 includes electrical routings composed of conductive traces 308 and vias 312 formed in the dielectric layers 306 for electrical connections between the integrated circuit (ICs) 102 and 104 on the redistribution layer structure 310-1 and the antenna 320 in the redistribution layer structure 310-2. In some embodiments, the redistribution layer structure 310-2 includes the antenna 320 formed in the dielectric layers 306. The antenna 320 is composed of the conductive layers, vias, and conductive pads. In addition, the redistribution layer structure 310-2 may further include radiators, feeding lines, another suitable components, or a combination thereof.

As shown in FIG. 6, the semiconductor package 500B further includes passivation layers 330-1, 330-2 disposed over the corresponding redistribution layer structures 310-1 and 310-2 of the substrate 300. In addition, the passivation layers 330-1 may have openings (not shown) to expose corresponding conductive pads 314 coupled to the conductive traces 308. In some embodiments, the passivation layers 230-1, 230-2, 330-1, 330-2 may have the same or similar materials and structures.

As shown in FIG. 6, the ICs 102 and 104 and the connector component 106 may be disposed over the same surface (e.g., the top surface 200BT) of the substrate 200B, and may be arranged close to the electrical routings of the redistribution layer structure 210-1B and far from the antenna 320 of the substrate 300. The ICs 102 and 104 and the connector component 106 may be arranged on the side of the substrate 200B which is opposite to the antenna 320 of the substrate 300.

As shown in FIG. 6, the shielding wall structure 460 is embedded in the substrate 200B. The shielding wall structure 460 is exposed from the top surface 200BT and/or the bottom surface 200BB of the substrate 200B and completely covered by the passivation layer 230-1 and/or 230-2 respectively. In addition, the shielding wall structure 460 is coupled to the shielding layer 250. Furthermore, the shielding wall structure 460 and the shielding layer 250 may be coupled by at least one ground trace (belong to a portion of the conductive traces 208) of the substrate 200B. The shielding wall structure 460 and the shielding layer 250 may prevent signals transmitted by the antenna 320 in a direction toward the ICs 102 and 104 and the electrical routings layers of the redistribution layer structures 210-1B and 210-2B, thereby reducing electromagnetic wave interference. In this embodiment, the shielding wall structure 460 does not extend into the substrate 300.

In some embodiments, the shielding wall structure 460 may include a non-conductive material wall 405 and a conductive material 404. In some embodiments, the conductive material 404 may be formed as a thin conductive layer covering sidewalls 405S and a bottom surface 405B of the non-conductive material wall 405. In some embodiments, the non-conductive material walls 205 and 405 may have the same or similar materials and structures. In some embodiments, the conductive materials 204 and 404 may have the same or similar materials and structures.

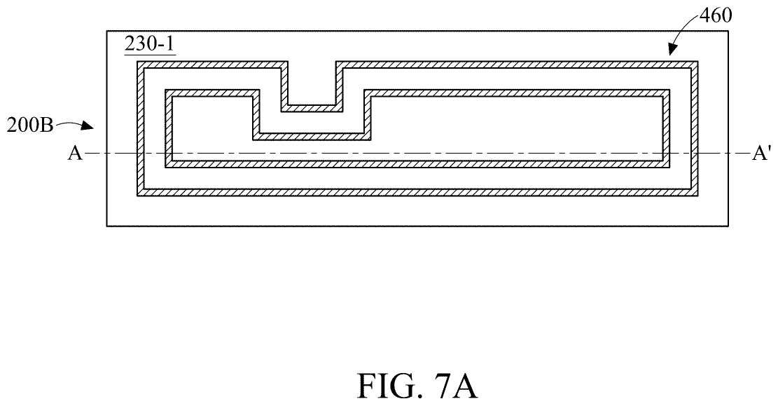

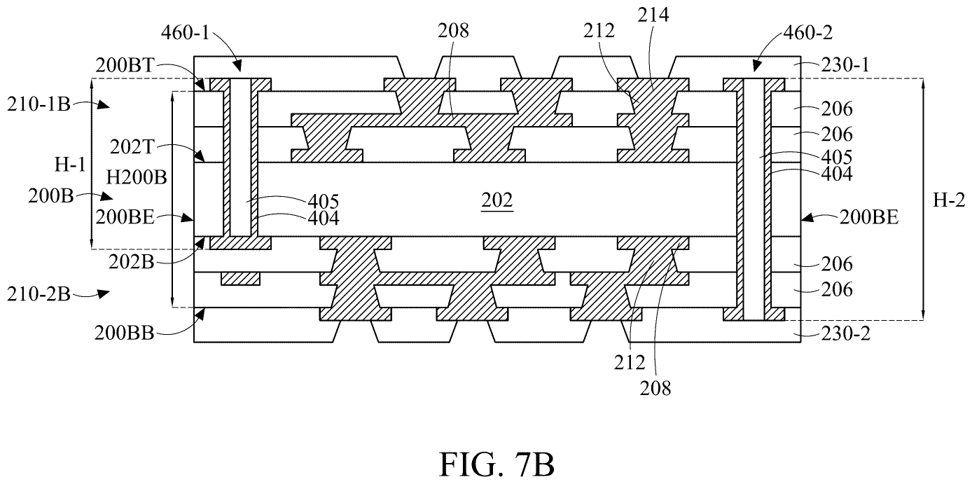

The structures and arrangements of the shielding wall structures 460 will be illustrated in FIGS. 7A and 7B.

FIG. 7A is a schematic top view of the substrate 200B of the semiconductor package 500B in accordance with some embodiments of the disclosure shown in FIG. 1. FIG. 7B is a cross-sectional view along the line A-A′ of the substrate 200B of the semiconductor package 500B in accordance with some embodiments of the disclosure shown in FIG. 7A. FIGS. 7A and 7B also illustrate the structure and arrangement of the shielding wall structure 460. Elements of the embodiments that are the same or similar to those previously described with reference to FIG. 1 are not repeated herein, in the interests of brevity. For illustration, the elements below the passivation layer 230-1 except for the shielding wall structure 460 are omitted in FIG. 7A.

As shown in FIGS. 7A and 7B, the shielding wall structure 460 may form a single closed pattern to surround the electrical routings (including at least one conductive trace 208, at least one via 212 and at least one conductive pad 214) of the substrate 200B coupled to the ICs 102 and 104 (FIG. 1). In some embodiments, as shown in FIG. 7A, the shielding wall structure 460 forms a closed and continuous pattern without any disconnected parts. The shielding wall structure 460 is separated from the sidewall 200BE of the substrate 200B. In other words, the shielding wall structure 460 is not exposed from the sidewall 200BE of the substrate 200B. In this embodiment, the shielding wall structure 460 may include portions 460-1 and 460-2 having different heights H-1 and H-2, as shown in FIG. 7B. For example, the portion 460-1 of the shielding wall structure 460 may pass through the RDL structure 210-1 and the core 202. The portion 460-2 of the shielding wall structure 460 may pass through the RDL structure 210-1, the core 202, and the RDL structure 210-2. In this embodiment, the portion 460-1 of the shielding wall structure 460 may be exposed form the top surface 200BT of the substrate 200B and the bottom surface 202B of the core 202. The portion 460-2 of the shielding wall structure 460 may be exposed form the top surface 200BT and the bottom surface 200BB of the substrate 200B of the core 202. In this embodiment, the height H-2 of portion 460-2 is greater than the height H-1 of portion 460-1. In this embodiment, the height H-2 may be greater than half a thickness H200B of the substrate 200B. The height H-1 may be smaller than the H200B of the substrate 200B. In some embodiments, the height H-2 may be greater than half the thickness H200B of the substrate 200B, while the height H-1 may be less than or equal to half the thickness H200B of the substrate 200B. Since the substrate 200B does not have an antenna embedded in it, at least a portion of the shielding wall structure 460 may pass through the substrate 200B to improve the shielding effect.

In this embodiment, since the portion 460-2 of the shielding wall structure 460 passes through the substrate 200B, the portion 460-1 of the shielding wall structure 460 may be designed not to passes through the substrate 200B (e.g., only passes through the RDL structure 210-1B of the substrate 200B), so that the portion of substrate 200B surrounded by the shielding wall structure 460 may keep connect to other portions of the substrate 200B. The integrity of the substrate 200B can be maintained accordingly.

In some embodiments, the number, shape trench, heights of portions of the shielding wall structure 460 shown in FIGS. 7A, 7B are only an example and is not a limitation to the present disclosure.

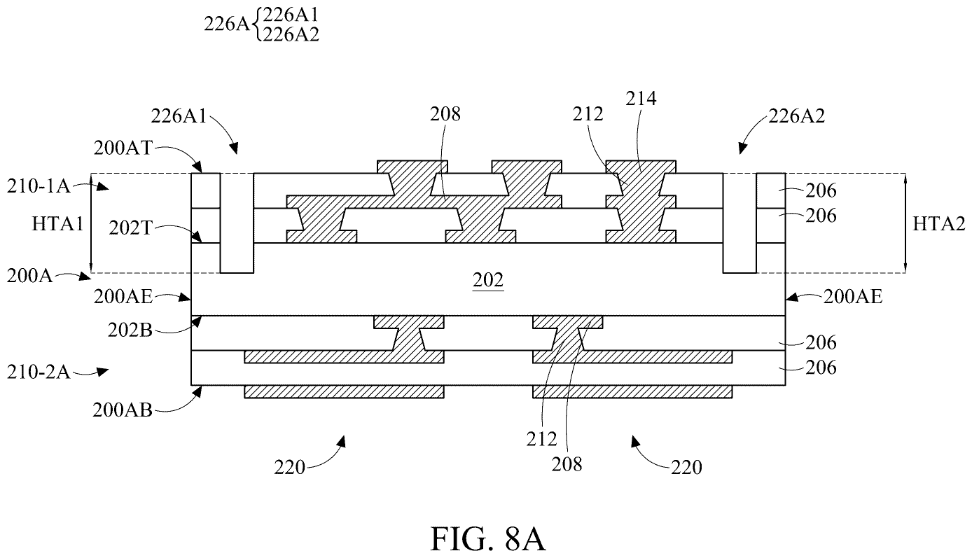

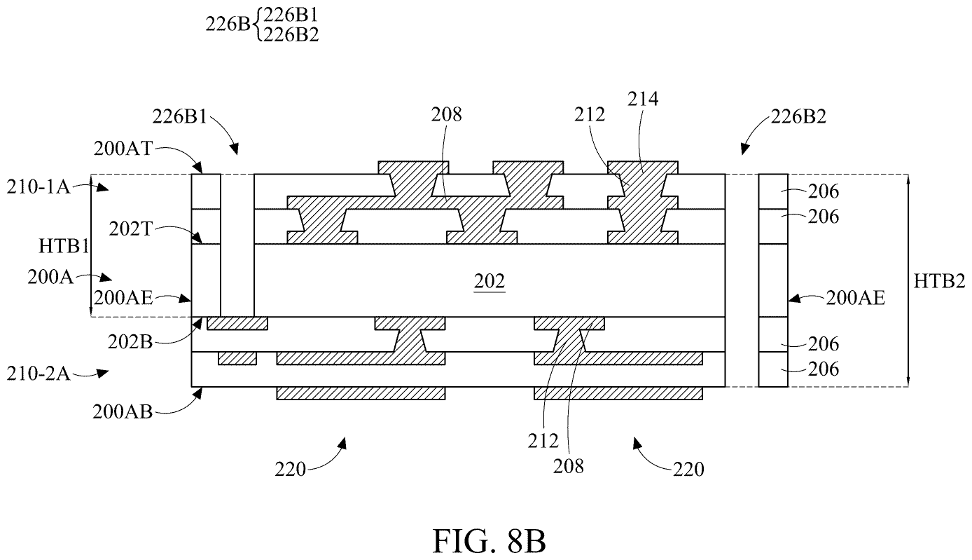

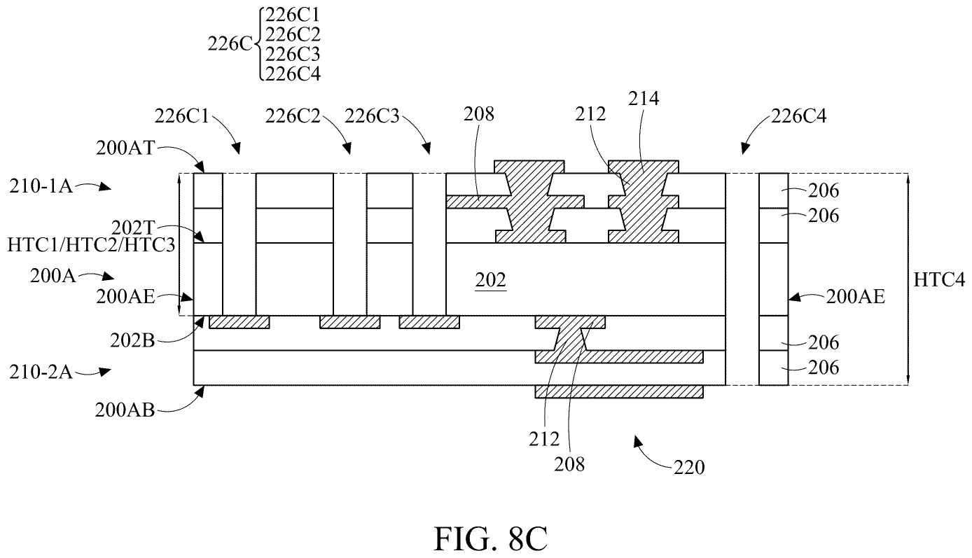

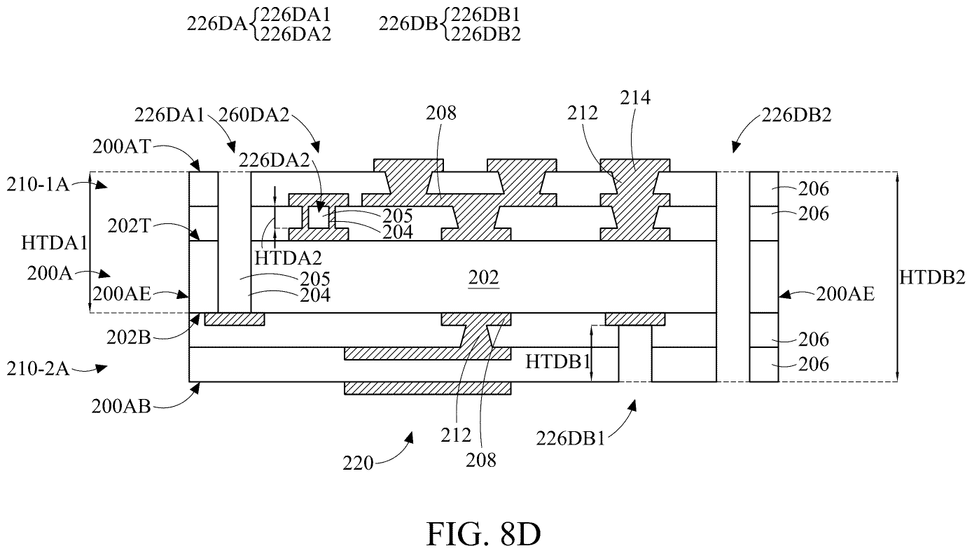

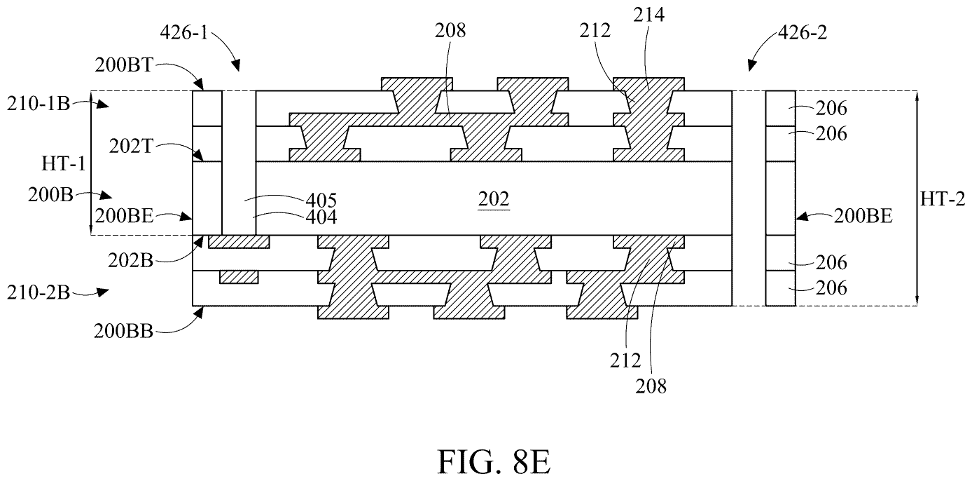

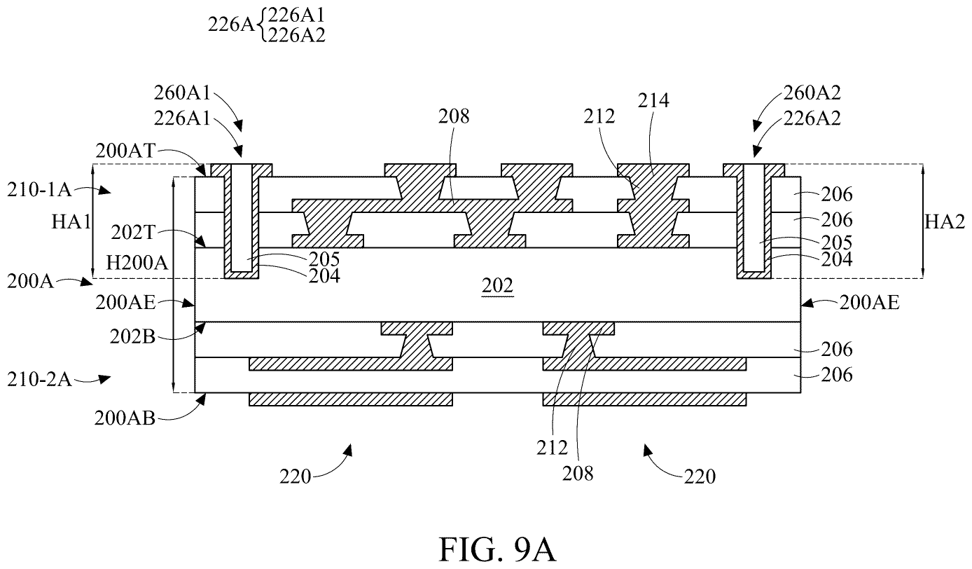

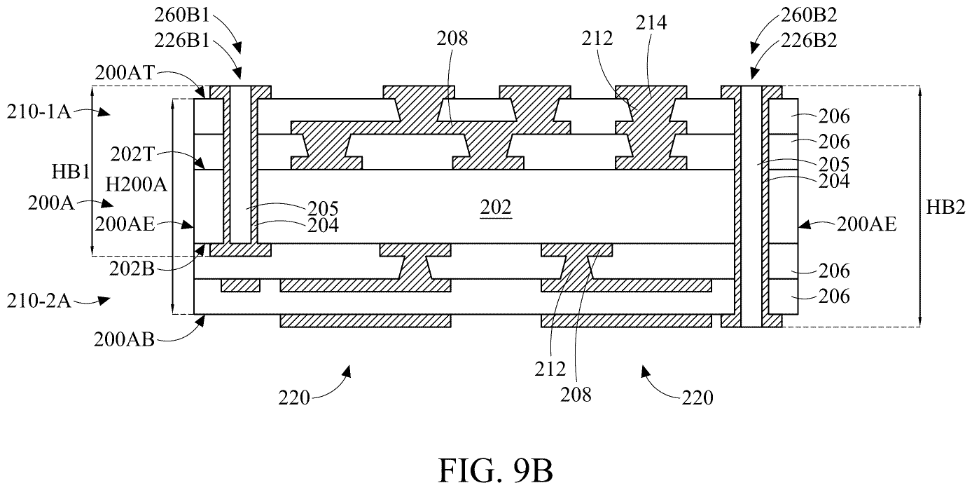

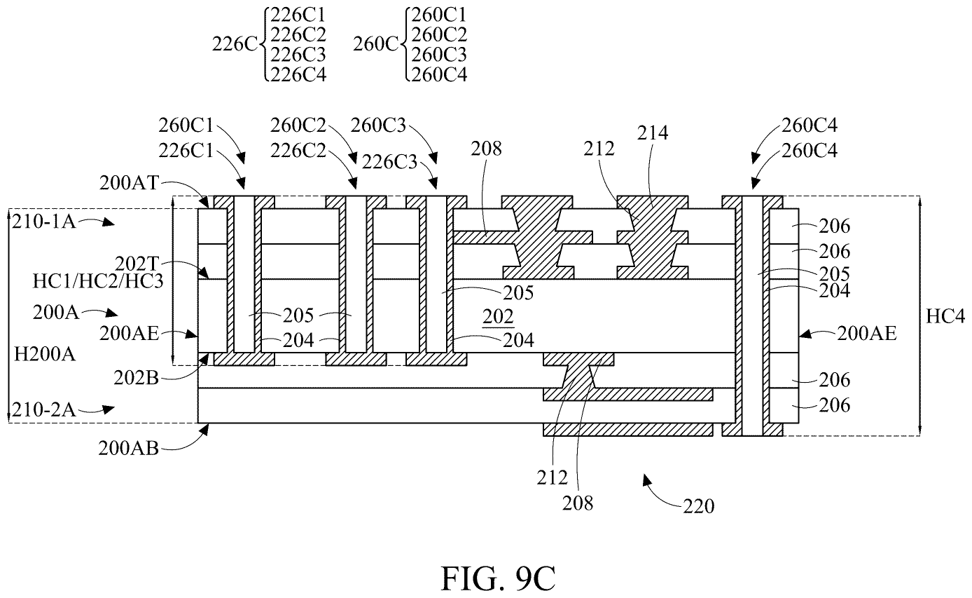

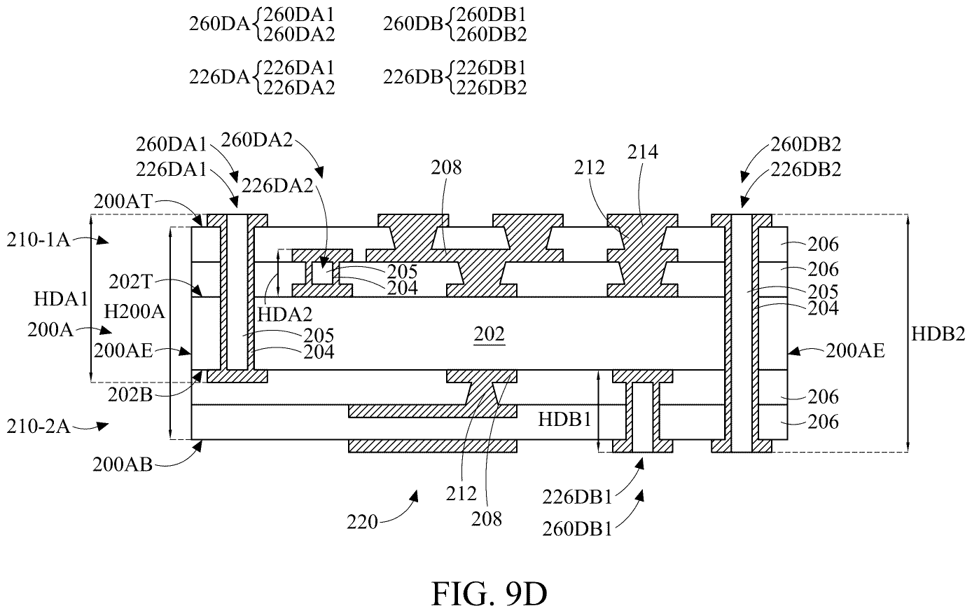

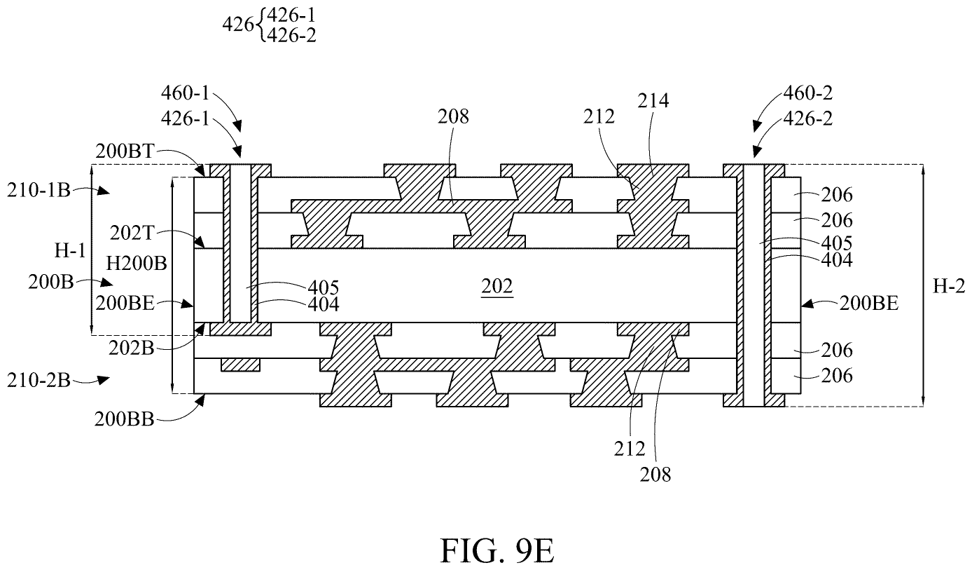

The methods for forming the semiconductor packages 500A and 500B are described below. FIGS. 8A, 8B, 8C, 8D, 8E, 9A, 9B, 9C, 9D and 9E are schematic cross-sectional views at different stages of forming the shielding wall structures 260A, 260B, 260C, 260DA, 260DB, and 460 in the substrates 200A and 200B (single unit) of the semiconductor packages 500A and 500B shown in FIGS. 2B, 3B, 4B, 5B, and 7B for the sake of the convenience, though the embodiments of the present disclosure are not limited thereto. In some embodiments, the method for forming the shielding wall structures may form periodically arranged shielding wall structures in the strip-formed substrate.

FIGS. 8A and 9A are schematic cross-sectional views at different stages of forming the shielding wall structure 260A of the semiconductor package 500A in accordance with some embodiments of the disclosure shown in FIG. 2B.

As shown in FIG. 8A, a substrate 200A is formed. In some embodiments, the substrate 200A may have a strip-form for fabricating a plurality of package units. The processes of forming the substrate 200A may include providing a core 202 having a top surface 202T and a bottom surface 202B. Next, RDL structures 210-1A and 210-2A including dielectric layers 206, conductive traces 208, vias 212 and conductive pads 214 are formed on the top surface 202T and the bottom surface 202B of the core 202 by a build-up process. In some embodiments, the antenna 220 is formed close to the bottom surface 200AB of the substrate 200A during the formation of the RDL structure 210-2A. Alternatively, when the substrate 200A is a coreless substrate, the processes of forming the substrate 200A may include laminating the dielectric layers 206 of the redistribution layer structures 210-2A on the dielectric layers 206 of the redistribution layer structure 210-1A (or vice versa).

Next, a trench 226A is formed in the substrate 200A by a milling process. In some embodiments, the trench 226A forms a closed pattern to define the position of the shielding wall structure 260A (FIG. 2A) to surround the electrical routings (including at least one conductive trace 208, at least one via 212 and at least one conductive pad 214) of the substrate 200A coupled to the subsequent formed integrated circuits (ICs) 102 and 104.

In some embodiments, the trench 226A may include portions 226A1 and 226A2. The portion 226A1 has height HTA1. The portion 226A2 has height HTA2. The heights HTA1 and HTA2 may be smaller than or equal to half the thickness H200A of the substrate 200A. In this embodiment, the height HTA1 and the height HTA2 may have substantially the same value. For example, the portions 226A1 and 226A2 of the trench 226A may pass through the RDL structure 210-1A and extend into a portion of the core 202.

Next, as shown in FIG. 9A, a conductive material 204 is formed on a portion of the top surface 200AT of the substrate 200A and lining sidewalls and the bottom surface of the trench 226A by a plating process. In some embodiments, the conductive material 204 does not fill up the trench 226A.

Next, a non-conductive material wall 205 is formed to fill the remaining space of the trench 226A by a deposition process and a subsequent etching backing process, so that the shielding wall structure 260A is formed. In some embodiments, the height HA1 of the portion 260A1 (and the height HA2 of the portion 260A2) of the resulting shielding wall structure 260A is greater than the height HTA1 of the portion 226A1 (and the height HTA2 of the portion 226A2) of the trench 226A.

Next, as shown in FIGS. 2A and 2B, passivation layers 230-1 and 230-2 are formed on the RDL structures 210-1A and 210-2A and the shielding wall structure 260A by a deposition process and a subsequent patterning process.

Next, as shown in FIG. 1, the ICs 102 and 104 and a connector component 106 are mounted on the top surface 200AT of the substrate 200A. The ICs 102 and 104 are coupled to the connector component 106 and the antenna 220. Next, a molding compound 110 encapsulating the ICs 102 and 104 by a molding process. Next, a shielding layer 250 is formed covering the molding compound 110 and the shielding wall structure 260A exposed from the top surface 200AT of the substrate 200A by a deposition process (e.g., sputtering). In some embodiments, the shielding wall structure 260A is coupled to the shielding layer 250.

Next, a singulation process is performed to cut the strip-formed substrate 200A into individual units. After the aforementioned processes, a discrete semiconductor package 500A as shown in FIG. 1 is formed.

FIGS. 8B and 9B are schematic cross-sectional views at different stages of forming the shielding wall structure 260B of the semiconductor package 500A in accordance with some embodiments of the disclosure shown in FIG. 3B.

As shown in FIG. 8B, a substrate 200A is formed. Next, a trench 226B is formed in the substrate 200A by a milling process. In some embodiments, the trench 226B forms a closed pattern to define the position of the shielding wall structure 260B (FIG. 3A) to surround the electrical routings (including at least one conductive trace 208, at least one via 212 and at least one conductive pad 214) of the substrate 200A coupled to the subsequent formed integrated circuits (ICs) 102 and 104.

In some embodiments, the trench 226B may include portions 226B1 and 226B2 having different heights HTB1 and HTB2. For example, the portion 226B1 of the trench 226B may pass through the RDL structure 210-1A and the core 202, and stop on the conductive trace 208 formed on the bottom surface 202B of the core 202. The portion 226B2 of the trench 226B may pass through the RDL structure 210-1A, the core 202, and the RDL structure 210-2A. In this embodiment, the height HTB2 of the portion 226B2 is greater than the height HTB1 of the portion 226B1. The height HTB2 may be greater than half the thickness H200A of the substrate 200A. The height HTA2 may be smaller than the thickness H200A of the substrate 200A.

Next, as shown in FIG. 9B, a conductive material 204 is formed lining sidewalls and a bottom surface of the trench 226B by a plating process. In some embodiments, the conductive material 204 does not fill up the trench 226B.

Next, a non-conductive material wall 205 is formed to fill the remaining space of the trench 226B by a deposition process and a subsequent etching backing process, so that the shielding wall structure 260B is formed. In some embodiments, the heights HB1 and HB2 of portions 260B1 and 260B2 of the resulting shielding wall structure 260B is greater than the heights HTB1 and HTB2 of portions 226B1 and 226B2 of the trench 226B.

Next, as shown in FIGS. 3A and 3B, passivation layers 230-1 and 230-2 are formed on the RDL structures 210-1A and 210-2A and the shielding wall structure 260B by a deposition process and a subsequent patterning process.

Next, as shown in FIG. 1, the ICs 102 and 104 and a connector component 106 are mounted on the top surface 200AT of the substrate 200A. The ICs 102 and 104 are coupled to the connector component 106 and the antenna 220. Next, a molding compound 110 encapsulating the ICs 102 and 104 by a molding process. Next, a shielding layer 250 is formed covering the molding compound 110 and the shielding wall structure 260B exposed from the top surface 200AT of the substrate 200A by a deposition process (e.g., sputtering). In some embodiments, the shielding wall structure 260B is coupled to the shielding layer 250.

Next, a singulation process is performed to cut the strip-formed substrate 200A into individual units. After the aforementioned processes, a discrete semiconductor package 500A as shown in FIG. 1 is formed.

FIGS. 8C and 9C are schematic cross-sectional views at different stages of forming the shielding wall structure 260C of the semiconductor package 500A in accordance with some embodiments of the disclosure shown in FIG. 4B.

As shown in FIG. 8C, a substrate 200A is formed. Next, a trench 226C is formed in the substrate 200A by a milling process. In some embodiments, the trench 226C forms a closed pattern to define the position of the shielding wall structure 260C (FIG. 4A) to surround the electrical routings (including at least one conductive trace 208, at least one via 212 and at least one conductive pad 214) of the substrate 200A coupled to the subsequent formed integrated circuits (ICs) 102 and 104.

In this embodiment, the trench 226C may include portions 226C1, 226C2, 226C3 and 226C4, as shown in FIG. 8C. The portion 226C1 has height THC1. The portion 226C2 has height HTC2. The portion 226C3 has height HTC3. The portion 226C4 has height HTC4. For example, portions 226C1, 226C2, and 226C3 of the trench 226C may pass through the RDL structure 210-1A and the core 202, and stop on the conductive traces 208 formed on the bottom surface 202B of the core 202. The portion 226C4 of the trench 226C may pass through the RDL structure 210-1A, the core 202, and the RDL structure 210-2A. In this embodiment, the height HTC1 of portion 226C1, the height HTC2 of portion 226C2, and the height HTC3 of portion 226C3 may have substantially the same value. In addition, the height HTC4 of portion 226C4 is greater than the height HTC1 of portion 226C1, the height HTC2 of portion 226C2, and the height HTC3 of portion 226C3. The height HTC4 may be greater than half the thickness H200A of the substrate 200A. The heights HTC1, HTC2, HTC3 may be smaller than the thickness H200A of the substrate 200A.

Next, as shown in FIG. 9C, a conductive material 204 is formed lining the trench 226C and extending to portions of the top surface 200AT and the bottom surface 200AB of the substrate 200A by a plating process. In some embodiments, the conductive material 204 does not fill up the trench 226C.

Next, a non-conductive material wall 205 is formed to fill the remaining space of the trench 226C by a deposition process and a subsequent etching backing process, so that the shielding wall structure 260C is formed. In some embodiments, the heights HC1, HC2, HC3 and HC4 of portions 260C1, 260C2, 260C3 and 260C4 of the resulting shielding wall structure 260C is greater than the heights HTC1, HTC2, HTC3 and HTC4 of portions 226C1, 226C2, 226C3 and 226C4 of the trench 226C.

Next, as shown in FIGS. 4A and 4B, passivation layers 230-1 and 230-2 are formed on the RDL structures 210-1A and 210-2A and the shielding wall structure 260C by a deposition process and a subsequent patterning process.

Next, as shown in FIG. 1, the ICs 102 and 104 and a connector component 106 are mounted on the top surface 200AT of the substrate 200A. The ICs 102 and 104 are coupled to the connector component 106 and the antenna 220. Next, a molding compound 110 encapsulating the ICs 102 and 104 by a molding process. Next, a shielding layer 250 is formed covering the molding compound 110 and the shielding wall structure 260C exposed from the top surface 200AT of the substrate 200A by a deposition process (e.g., sputtering). In some embodiments, the shielding wall structure 260C is coupled to the shielding layer 250.

Next, a singulation process is performed to cut the strip-formed substrate 200A into individual units. After the aforementioned processes, a discrete semiconductor package 500A as shown in FIG. 1 is formed.

FIGS. 8D and 9D are schematic cross-sectional views at different stages of forming the shielding wall structures 260DA and 260DB of the semiconductor package 500A in accordance with some embodiments of the disclosure shown in FIG. 5B.

As shown in FIG. 8D, a substrate 200A is formed. In this embodiment, a portion 260DA2 of the shielding wall structure 260DA is formed during the formation of the RDL layer structure 210-1. More specifically, a portion 226DA2 of a trench 226DA having a height HTDA2 is formed in the dielectric layer 206 and on the conductive trace 208 directly on the top surface 202T of the core 202 by a patterning process. Next, a portion of a conductive material 204 is formed lining sidewalls and a bottom surface of the portion 226DA2 of the trench 226DA by a plating process. In some embodiments, the portion of the conductive material 204 does not fill up the 226DA2 of the trench 226DA. Next, a portion of a non-conductive material wall 205 is formed to fill the remaining space of the portion 226DA2 of the trench 226DA by a deposition process and a subsequent etching backing process, so that the portion 260DA2 of the shielding wall structure 260DA is formed.

Next, the remaining portion of the trench 226DA and a trench 206 DB is formed in the substrate 200A by a milling process. In some embodiments, the trenches 226DA and 226 DB forms closed patterns separated from each other to define the positions of the shielding wall structures 260DA and 260DB (FIG. 5A) to surround the electrical routings (including at least one conductive trace 208, at least one via 212 and at least one conductive pad 214) of the substrate 200A coupled to the subsequent formed integrated circuits (ICs) 102 and 104.

In this embodiment, the trench 226DA may include portions 226DA1 and 226DA2 having heights HTDA1 and HTDA2. The trench 226 DB may include portions 226DB1 and 226DB2 having heights HTDB1 and HTDB2. For example, the portion 226DA1 of the trench 226DA may pass through the RDL structure 210-1A and the core 202, and stop on the conductive trace 208 formed on the bottom surface 202B of the core 202. The portion 226DA2 of the trench 226DA may pass through one dielectric layer 206 of the RDL structure 210-1A, and stop on the conductive traces 208 formed on the top surface 202T of the core 202. The portion 226DB1 of the trench 226 DB may pass through two dielectric layers 206 of the RDL structure 210-2A, and stop on another conductive trace 208 formed on the bottom surface 202B of the core 202. The portion 226DB2 of the trench 226 DB may pass through the RDL structure 210-1A, the core 202, and the RDL structure 210-2A. In this embodiment, the height HTDB2 of portion 226DB2 is greater than the height HTDA1 of portion 226DA1. The height HTDA1 of portion 226DA1 is greater than the height HTDB1 of portion 226DB1. The height HTDB1 of portion 226DB1 is greater than the height HTDA2 of portion 226DA2. The heights HTDA1 and HTDB2 may be greater than half the thickness H200A of the substrate 200A. The heights HTDA2 and HTDB1 may be smaller than half the thickness H200A of the substrate 200A.

Next, as shown in FIG. 9D, the remaining portion of the conductive material 204 is formed lining the trench 226 DB and the remaining portion of the trench 226DA and extending to portions of the top surface 200AT and/or the bottom surface 200AB of the substrate 200A. In some embodiments, the remaining portion of the conductive material 204 does not fill up the remaining portion of the trenches 226DA and 226 DB.

Next, the remaining portion of the non-conductive material wall 205 is formed to fill the remaining space of the trench 226 DB and the remaining portion of the trench 226DA by a deposition process and a subsequent etching backing process, so that the shielding wall structures 260DA and 260DB formed. In some embodiments, the heights HDA1, HDA2 of portions 260DA1 and 260DA2 of the resulting shielding wall structure 260DA are greater than the heights HTDA1, HTDA2 of portions 226DA1 and 226DA2 of the trench 226DA. The heights HDB1, HDB2 of portions 260DB1 and 260DB2 of the resulting shielding wall structure 260DB are greater than the heights HTDB1, HTDB2 of portions 226DB1 and 226DB2 of the trench 226 DB.

Next, as shown in FIGS. 5A and 5B, passivation layers 230-1 and 230-2 are formed on the RDL structures 210-1A and 210-2A and the shielding wall structures 260DA and 260DB by a deposition process and a subsequent patterning process.

Next, as shown in FIG. 1, the ICs 102 and 104 and a connector component 106 are mounted on the top surface 200AT of the substrate 200A. The ICs 102 and 104 are coupled to the connector component 106 and the antenna 220. Next, a molding compound 110 encapsulating the ICs 102 and 104 by a molding process. Next, one or more shielding layers 250 are formed covering the molding compound 110 and the shielding wall structures 260DA and 260DB exposed from the top surface 200AT of the substrate 200A by a deposition process (e.g., sputtering). In some embodiments, the shielding wall structures 260DA and 260DB are coupled to the shielding layer 250.

Next, a singulation process is performed to cut the strip-formed substrate 200A into individual units. After the aforementioned processes, a discrete semiconductor package 500A as shown in FIG. 1 is formed.

FIGS. 8E and 9E are schematic cross-sectional views at different stages of forming the shielding wall structure 460 of the semiconductor package 500B in accordance with some embodiments of the disclosure shown in FIG. 7B.

As shown in FIG. 8E, a substrate 200B is formed. In some embodiments, the substrate 200B may have a strip-form for fabricating a plurality of package units. The processes of forming the substrate 200B may include providing a core 202 having a top surface 202T and a bottom surface 202B. Next, RDL structures 210-1B and 210-2B including dielectric layers 206, conductive traces 208, vias 212 and conductive pads 214 are formed on the top surface 202T and the bottom surface 202B of the core 202 by a build-up process.

Next, a trench 426 is formed in the substrate 200B by a milling process. In some embodiments, the trench 426 forms a closed pattern to define the position of the shielding wall structure 460 (FIG. 3A) to surround the electrical routings (including at least one conductive trace 208, at least one via 212 and at least one conductive pad 214) of the substrate 200B coupled to the subsequent formed integrated circuits (ICs) 102 and 104.

In some embodiments, the trench 426 may include portions 426-1 and 426-2 having different height HT-1 and HT-2. For example, the portion 426-1 of the trench 426 may pass through the RDL structure 210-1B and the core 202, and stop on the conductive trace 208 formed on the bottom surface 202B of the core 202. The portion 426-2 of the trench 426 may pass through the RDL structure 210-1B, the core 202, and the RDL structure 210-2B. In this embodiment, the height HT-2 of portion 426-2 is greater than the height HT-1 of portion 426-1. The height HT-2 may be greater than half the thickness H200B of the substrate 200B. The height HT-1 may be smaller than the thickness H200B of the substrate 200B.

Next, as shown in FIG. 9E, a conductive material 404 is formed lining the trench 426 and extending to portions of the top surface 200BT and/or the bottom surface 200BB of the substrate 200B by a plating process. In some embodiments, the conductive material 204 does not fill up the trench 426.

Next, a non-conductive material wall 405 is formed to fill the remaining space of the trench 426 by a deposition process and a subsequent etching backing process, so that the shielding wall structure 460 is formed. In some embodiments, the heights H-1 and H-2 of portions 460-1 and 460-2 of the resulting shielding wall structure 460 are greater than the heights HT-1 and HT-2 of portions 426-1 and 426-2 of the trench 426.

Next, as shown in FIGS. 7A and 7B, passivation layers 230-1 and 230-2 are formed on the RDL structures 210-1B and 210-2B and the shielding wall structure 460 by a deposition process and a subsequent patterning process.

Next, as shown in FIG. 1, the ICs 102 and 104 and a connector component 106 are mounted on the top surface 200BT of the substrate 200B. The ICs 102 and 104 are coupled to the connector component 106 and the antenna 220. Next, a molding compound 110 encapsulating the ICs 102 and 104 by a molding process. Next, a shielding layer 250 is formed covering the molding compound 110 and the shielding wall structure 460 exposed from the top surface 200BT of the substrate 200B by a deposition process (e.g., sputtering). In some embodiments, the shielding wall structure 460 is coupled to the shielding layer 250. Next, the intermediate structure including the substrate 200B, the shielding wall structure 460, the passivation layers 230-1 and 230-2, the ICs 102 and 104, the connector component 106, the molding compound 110, and the shielding layer 250 is mounted on a substrate 300 including an antenna 320 via conductive structures 222.

Next, a singulation process is performed to cut the strip-formed substrate 200A into individual units. After the aforementioned processes, a discrete semiconductor package 500A as shown in FIG. 1 is formed.

Embodiments provide a semiconductor package and a method for forming a semiconductor package (e.g., the semiconductor packages 500A and 500B), such as an antenna-in-module/package (AiM/AiP). The semiconductor package includes a shielding wall structure (e.g., the shielding wall structures 260A, 260B, 260C, 260D, and 460) embedded in the substrate (e.g., the substrate 200) and coupled to the shielding layer (e.g., the shielding layer 250) shielding one or more integrated circuits (e.g., the ICs 102 and 104) disposed on the substrate. The shielding wall structure may serve as an extending portion of the shielding layer to surround the electrical routings (e.g., at least one conductive trace 208, at least one via 212 and at least one conductive pad 214) of the substrate coupled to the integrated circuits. Therefore, the shielding layer is not required to cover a sidewall of the substrate (e.g., the sidewall 200AE of the substrate 200A and the sidewall 200BE of the substrate 200B). In some embodiments, the shielding wall structure may be formed by plating a conductive material (e.g., the conductive material 204) in the trench (e.g., the trenches 226A, 226B, 226C, 226DA, 226 DB, and 426) created in the substrate before forming the shielding layer. Therefore, the height (e.g., the heights HA1, HA2, HB1, HB2, HC1, HC2, HC3, HC4, HD1, HD2, H-1, H-2) of the shielding wall structure may be precisely controlled by the height (e.g., the heights HTA1, HTA2, HTB1, HTB2, HTC1, HTC2, HTC3, HTC4, HTD1, HTD2, HT-1, HT-2) of the trench. In some embodiments, the number, top-view shape, heights of portions of the shielding wall structure may be varied according to product designs. The processes of the shielding wall structure can be integrated in the processes for forming the substrate, so that the tooling fee and the tooling maintenance fee for the partial shielding can be reduced. In addition, the periodically arranged shielding wall structures can be simultaneously formed in the strip-formed substrate. Discrete semiconductor package units are formed after the formations of the shielding wall structure, the integrated circuits and the shielding layer. Therefore, the method for forming the semiconductor package may have a high throughput.

Embodiments provide a semiconductor package. The semiconductor package includes a first substrate, a first integrated circuit (IC), an antenna, a molding compound, a shielding layer, and a first shielding wall structure. The first substrate includes a first surface and a second surface opposite to each other. The antenna is located close to a first surface of the first substrate. The first integrated circuit (IC) is mounted on a second surface of the first substrate and is coupled to the antenna. The molding compound encapsulates the first IC. The shielding layer covers the molding compound. The first shielding wall structure is embedded in the first substrate and coupled to the shielding layer.

In some embodiments, the first shielding wall structure includes a non-conductive material wall and a conductive material. The conductive material covers sidewalls and a bottom surface of the non-conductive material wall.

In some embodiments, the first shielding wall structure is exposed from the first substrate and completely covered by a passivation layer.

In some embodiments, the first shielding wall structure is separated from a sidewall of the first substrate.

In some embodiments, the first shielding wall structure is coupled to a ground trace of the first substrate.

In some embodiments, the first shielding wall structure forms a closed pattern to surround at least one conductive trace of the first substrate coupled to the first IC.

In some embodiments, the first shielding wall structure includes a first portion having a first height and a second portion having a second height.

In some embodiments, the first substrate includes a core, first dielectric layers, and second dielectric layers. The core has a third surface and a fourth surface. The third surface is close to the first surface of the first substrate, and the fourth surface is close to the second surface of the first substrate. The first dielectric layers are disposed on the third surface of the core. The second dielectric layers are disposed on the fourth surface of the core.

In some embodiments, the antenna is formed in dielectric layers of the first substrate far from the first integrated circuit (IC).

In some embodiments, the first height is the same as the second height, and the first portion and the second portion of the first shielding wall structure pass through at least one of the first dielectric layers and are embedded in the core of the first substrate. The first height and the second height are smaller than or equal to half a thickness of the first substrate.

In some embodiments, the first height is greater than the second height, and the first portion of the first shielding wall structure passes through at least one of the first dielectric layers, the core and at least one of the second dielectric layers of the first substrate. The first height and the second height are smaller than or equal to half a thickness of the first substrate.

In some embodiments, the first height is greater than the second height, and the second portion of the first shielding wall structure passes through at least one of the first dielectric layers or at least one of the second dielectric layers. The second height is smaller than the thickness of the first substrate.

In some embodiments, the semiconductor package further includes a second shielding wall structure embedded in the substrate and coupled to the shielding layer. The first shielding wall structure and the second shielding wall structure are separated from each other.

In some embodiments, at least one of the first shielding wall structure and the second shielding wall structure is coupled to the shielding layer by at least one conductive trace of the first substrate.

In some embodiments, each of the first shielding wall structure and the second shielding wall structure forms a closed pattern to surround at least one conductive trace of the first substrate coupled to the first IC.

In some embodiments, the semiconductor package further includes a second substrate mounted on the first surface of the first substrate. The antenna is disposed in the second substrate.

In some embodiments, the first shielding wall structure does not extend into the second substrate.

In some embodiments, the shielding wall structure forms a closed and continuous pattern without any disconnected parts.

In some embodiments, at least one portion of the shielding wall structure has a height smaller than the thickness of the substrate.

Embodiments provide a method for forming a semiconductor package. The method includes forming a first substrate. The first substrate includes a first surface and a second surface opposite to each other. The method further includes forming a first shielding wall structure embedded in the first substrate. The method further includes forming an antenna close to a first surface of the substrate. The method further includes mounting a first integrated circuit (IC) on a second surface of the first substrate and coupled to the antenna. The method further includes forming a molding compound encapsulating the first IC. The method further includes forming a shielding layer covering the molding compound, wherein the first shielding wall structure is coupled to the shielding layer.

In some embodiments, the formation of the first substrate includes providing a core having a third surface and a fourth surface. The third surface is close to the first surface of the first substrate, and the fourth surface is close to the second surface of the first substrate. The formation of the first substrate includes forming first dielectric layers on the third surface of the core. The formation of the first substrate includes forming second dielectric layers on the fourth surface of the core.

In some embodiments, the formation of the first substrate includes laminating dielectric layers.

In some embodiments, the method further includes forming a trench in the first substrate, wherein the trench forms a closed pattern to surround at least one conductive trace of the first substrate coupled to the first IC. The method further includes forming a conductive material lining sidewalls and a bottom surface of the trench. The method further includes filling the trench with a non-conductive material to form the first shielding wall structure. The method further includes forming a passivation layer on the first shielding wall structure.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor package, comprising:
a first substrate comprising a first surface and a second surface opposite to each other;
an antenna located close to the first surface of the first substrate;
a first integrated circuit (IC) mounted on the second surface of the first substrate and coupled to the antenna;
a molding compound encapsulating the first IC;
a shielding layer covering the molding compound; and
a first shielding wall structure embedded in the first substrate and coupled to the shielding layer.

2. The semiconductor package as claimed in claim 1, wherein the first shielding wall structure comprises:
a non-conductive material wall; and
a conductive material covering sidewalls and a bottom surface of the non-conductive material wall.

3. The semiconductor package as claimed in claim 1, wherein the first shielding wall structure is exposed from the first substrate and completely covered by a passivation layer.

4. The semiconductor package as claimed in claim 1, wherein the first shielding wall structure is separated from a sidewall of the first substrate.

5. The semiconductor package as claimed in claim 1, wherein the first shielding wall structure is coupled to a ground trace of the first substrate.

6. The semiconductor package as claimed in claim 1, wherein the first shielding wall structure forms a closed pattern to surround at least one conductive trace of the first substrate coupled to the first IC.

7. The semiconductor package as claimed in claim 1, wherein the first shielding wall structure comprises:
a first portion having a first height; and
a second portion having a second height.

8. The semiconductor package as claimed in claim 1, wherein the antenna is formed in dielectric layers of the first substrate far from the first integrated circuit (IC).

9. The semiconductor package as claimed in claim 7, wherein the first height is the same as the second height, and the first height and the second height are smaller than or equal to half a thickness of the first substrate.

10. The semiconductor package as claimed in claim 7, wherein the first height is greater than the second height, and the first height is greater than half a thickness of the first substrate.

11. The semiconductor package as claimed in claim 10, wherein the first height is greater than the second height, and the second height is smaller than the thickness of the first substrate.

12. The semiconductor package as claimed in claim 1, further comprising:
a second shielding wall structure embedded in the first substrate and coupled to the shielding layer,
wherein the first shielding wall structure and the second shielding wall structure are separated from each other.

13. The semiconductor package as claimed in claim 12, wherein at least one of the first shielding wall structure and the second shielding wall structure is coupled to the shielding layer by at least one conductive trace of the first substrate.

14. The semiconductor package as claimed in claim 12, wherein each of the first shielding wall structure and the second shielding wall structure forms a closed pattern to surround at least one conductive trace of the first substrate coupled to the first IC.

15. The semiconductor package as claimed in claim 1, further comprising:
a second substrate mounted on the first surface of the first substrate, wherein the antenna is disposed in the second substrate.

16. The semiconductor package as claimed in claim 15, wherein the first shielding wall structure does not extend into the second substrate.

17. The semiconductor package as claimed in claim 1, wherein the shielding wall structure forms a closed and continuous pattern without any disconnected parts.

18. The semiconductor package as claimed in claim 1, wherein at least one portion of the shielding wall structure has a height smaller than the thickness of the substrate.

19. A method for forming a semiconductor package, comprising:
forming a first substrate comprising a first surface and a second surface opposite to each other;
forming a first shielding wall structure embedded in the first substrate;
forming an antenna close to the first surface of the substrate;
mounting a first integrated circuit (IC) on the second surface of the first substrate and coupled to the antenna;
forming a molding compound encapsulating the first IC; and
forming a shielding layer covering the molding compound, wherein the first shielding wall structure is coupled to the shielding layer.

20. The method for forming a semiconductor package as claimed in claim 19, further comprising:
forming a trench in the first substrate, wherein the trench forms a closed pattern to surround at least one conductive trace of the first substrate coupled to the first IC;
forming a conductive material lining sidewalls and a bottom surface of the trench;
filling the trench with a non-conductive material to form the first shielding wall structure; and
forming a passivation layer on the first shielding wall structure.
